(19) United States
(12) Patent Application Publication
(10) Pub. No.: US 2026/0123368 A1
(43) Pub. Date: Apr. 30, 2026

(54) METHOD OF MANUFACTURING INTEGRATED CIRCUIT DEVICE

(71) Applicant: Samsung Electronics Co., Ltd., Suwon-si (KR)

(72) Inventors: Sanghoon AHN, Suwon-si (KR); Woongpil JEON, Suwon-si (KR); Yongsoon CHOI, Suwon-si (KR); Inwoo KIM, Suwon-si (KR); Yongkwan KIM, Suwon-si (KR); Huijung KIM, Suwon-si (KR)

(73) Assignee: Samsung Electronics Co., Ltd., Suwon-si (KR)

(21) Appl. No.: 19/361,315

(22) Filed: Oct. 17, 2025

(30) Foreign Application Priority Data
Oct. 28, 2024 (KR) 10-2024-0148965

(51) Int. Cl. H01L 21/033

(52) U.S. Cl. CPC H10P 76/4085; H10P 76/405; H10P 76/4083

(57) ABSTRACT

A method of manufacturing an integrated circuit device includes forming a mandrel pattern having a stack structure including a mandrel base pattern and a mandrel hard mask pattern on a base layer, attaching precursor inhibitors to surfaces of the base layer and the mandrel hard mask pattern, forming a side surface spacer layer on a side surface of the mandrel base pattern, removing a first portion of the precursor inhibitors, leaving a second portion of the precursor inhibitors between the base layer and the side surface spacer layer, forming a spacer bonding layer by modifying the second portion of the precursor inhibitors, and then forming a spacer pattern with a stack structure including the spacer bonding layer and the side surface spacer layer, removing the mandrel pattern, and forming a base pattern by patterning the base layer by using the spacer pattern as an etch mask.

### CROSS-REFERENCE TO RELATED APPLICATION

This application is based on and claims priority under 35 U.S.C. § 119 to Korean Patent Application No. 10-2024-0148965, filed on Oct. 28, 2024, in the Korean Intellectual Property Office, the disclosure of which is incorporated by reference herein in its entirety.

### BACKGROUND

The inventive concepts relate to methods of manufacturing an integrated circuit device, and more particularly, to methods of manufacturing an integrated circuit device utilizing a multi-patterning technique.

With the rapid development of the electronics industry and the growing demands of users, electronic devices have been miniaturized while achieving higher performance, and thus, the downscaling of integrated circuit devices included in electronic devices has progressed rapidly. Accordingly, multi-patterning technologies, such as Double Patterning Technology (DPT) and Quadruple Patterning Technology (QPT), have been introduced to manufacture integrated circuit devices.

### SUMMARY

The inventive concepts provide methods of manufacturing an integrated circuit device capable of forming patterns with improved uniformity.

According to an example embodiment of the inventive concepts, a method of manufacturing an integrated circuit device may include forming a mandrel pattern on a base layer, the mandrel pattern having a stack structure that includes a mandrel base pattern and a mandrel hard mask pattern, attaching precursor inhibitors to a surface of the base layer and a surface of the mandrel hard mask pattern, forming a side surface spacer layer on a side surface of the mandrel base pattern, removing a first portion of the precursor inhibitors, leaving a second portion of the precursor inhibitors between the base layer and the side surface spacer layer, forming a spacer bonding layer by modifying the second portion of the precursor inhibitors to bond the base layer to the side surface spacer layer, and then forming a spacer pattern with a stack structure including the spacer bonding layer and the side surface spacer layer, removing the mandrel pattern, and forming a base pattern by patterning the base layer by using the spacer pattern as an etch mask.

According to an example embodiment of the inventive concepts, a method of manufacturing an integrated circuit device may include forming a mandrel pattern on a base layer, the mandrel pattern having a stack structure that includes a mandrel base pattern and a mandrel hard mask pattern, exposing a surface of the base layer and a surface of the mandrel hard mask pattern to precursor inhibitors such that the precursor inhibitors are not attached to a surface of the mandrel base pattern but a first ligand of each of the precursor inhibitors is attached to the surface of the base layer and the surface of the mandrel hard mask pattern, the precursor inhibitors each including a central element, the first ligand that is a bonding moiety bonded to the central element, and a second ligand that is an inhibition moiety, forming a side surface spacer layer on a side surface of the mandrel base pattern, among the precursor inhibitors, leaving a first portion of the precursor inhibitors attached to a portion of the surface of the base layer between the base layer and the side surface spacer layer and removing the second portion of the precursor inhibitors attached to another portion of the surface of the base layer and the surface of the mandrel hard mask pattern, forming a spacer bonding layer by modifying the first portion of the precursor inhibitors to bond the base layer to the side surface spacer layer, and then forming a spacer pattern with a stack structure including the spacer bonding layer and the side surface spacer layer, removing the mandrel pattern, and forming a base pattern by patterning the base layer by using the spacer pattern as an etch mask.

According to an example embodiment of the inventive concepts, a method of manufacturing an integrated circuit device may include forming a mandrel pattern on a base layer, the mandrel pattern having a stack structure that includes a mandrel base pattern and a mandrel hard mask pattern, performing surface treatment with hydrogen radicals to make each of a surface of the base layer and a surface of the mandrel hard mask pattern hydrophilic and a surface of the mandrel base pattern hydrophobic, exposing the surface of the base layer and the surface of the mandrel hard mask pattern to precursor inhibitors such that the precursor inhibitors are attached to the surface of the base layer and the surface of the mandrel hard mask pattern through a first ligand of each of the precursor inhibitors, the precursor inhibitors each including a central element, the first ligand functioning as a bonding moiety bonded to the central element, and a second ligand functioning as an inhibition moiety, performing a preprocessing process of flowing H₂O onto the base layer and the mandrel pattern, forming a side surface spacer layer on a side surface of the mandrel base pattern of the mandrel pattern by using a reactant that does not react with the precursor inhibitors and a spacer deposition precursor that reacts with the reactant, such that the side surface spacer layer and the base layer are spaced apart from each other with the precursor inhibitors therebetween, among the precursor inhibitors, leaving a first portion of the precursor inhibitors attached to portions of the surface of the base layer between the base layer and the side surface spacer layer and removing a second portion of the precursor inhibitors attached to other portions of the surface of the base layer and the surface of the mandrel hard mask pattern, forming a spacer bonding layer, which bonds the base layer to the side surface spacer layer, by changing the first portion of the precursor inhibitors due to ozone (O₃) or plasma containing oxygen radicals (O₂, H₂O, N₂O, CO₂, or NO) and forming a spacer pattern with a stack structure including the spacer bonding layer and the side surface spacer layer, removing the mandrel pattern, and forming a base pattern by patterning the base layer by using the spacer pattern as an etch mask.

### BRIEF DESCRIPTION OF THE DRAWINGS

Example embodiments will be more clearly understood from the following detailed description taken in conjunction with the accompanying drawings in which:

FIG. 1 is a flowchart of a method of manufacturing an integrated circuit device, according to an example embodiment;

FIGS. 2A and 2B are conceptual views of integrated circuit devices manufactured according to a method of manufacturing an integrated circuit device, according to some example embodiments;

FIGS. 3A to 3K are cross-sectional views illustrating a method of manufacturing an integrated circuit device, according to an example embodiment;

FIGS. 4A and 4B are cross-sectional illustrating of a method of manufacturing an integrated circuit device, according to an example embodiment;

FIGS. 5A to 5F are conceptual views for describing a method of manufacturing an integrated circuit device, according to an example embodiment;

FIGS. 6A and 6B are cross-sectional views illustrating a method of manufacturing an integrated circuit device, according to an example embodiment;

FIGS. 7A to 7E are cross-sectional views illustrating a method of manufacturing an integrated circuit device, according to an example embodiment;

FIG. 8 is a flowchart of a method of manufacturing an integrated circuit device, according to an example embodiment;

FIGS. 9A to 9H are cross-sectional views illustrating a method of manufacturing an integrated circuit device, according to an example embodiment; and

FIGS. 10A to 10D are cross-sectional views illustrating a method of manufacturing an integrated circuit device, according to an embodiment.

### DETAILED DESCRIPTION

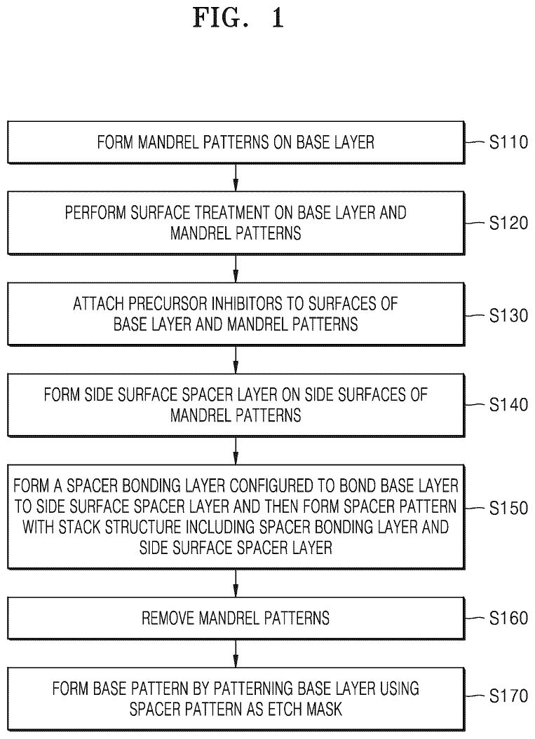

FIG. 1 is a flowchart of a method of manufacturing an integrated circuit device, according to an example embodiment.

Referring to FIG. 1, in operation S110, a mandrel pattern is formed on a base layer. The mandrel pattern may be formed to have a stack structure including a mandrel base pattern and a mandrel hard mask pattern. In some example embodiments, for example, the surface of the base layer, the surface of the mandrel base pattern, and the surface of the mandrel hard mask pattern may each be hydrophilic.

In operation S120, after the mandrel pattern is formed, surface treatment is performed on the base layer and the mandrel pattern. For example, through hydrogen (H) radial treatment, the surface of the mandrel base pattern may be reduced to become hydrophobic, and each of the surfaces of the base layer and the mandrel hard mask pattern may remain hydrophilic.

In operation S130, the surface of the base layer and the surface of the mandrel pattern are exposed to precursor inhibitors (PIs) such that the PIs are attached to the surfaces of the base layer and the mandrel hard mask pattern of the mandrel pattern. The PIs may be attached to the surfaces of the base layer and the mandrel hard mask pattern, both of which are hydrophilic, and may not be attached to the surface of the mandrel base pattern, which is hydrophobic.

In operation S140, a side surface spacer layer is formed on side surfaces of the mandrel pattern. The side surface spacer layer may be formed only on the surface of the mandrel base pattern but may not be formed on the surface of the base layer and the surface of the mandrel hard mask pattern.

In operation S150, a spacer bonding layer for bonding the base layer to the side surface spacer layer is formed, and a spacer pattern with a stack structure of the spacer bonding layer and the side surface spacer layer is formed. The spacer bonding layer may be formed by modifying the PIs. The spacer bonding layer may be between the upper surface of the base layer and the lower surface of the side surface spacer layer and bond the base layer to the side surface spacer layer.

In operation S160, the mandrel pattern is removed, leaving the spacer pattern on the base layer. Then, in operation S170, the base layer is patterned using the spacer pattern as an etch mask, thereby forming a base pattern. In some example embodiments, a target layer located on the lower portion of the base pattern may be patterned using the base pattern as an etch mask, thereby forming a target pattern.

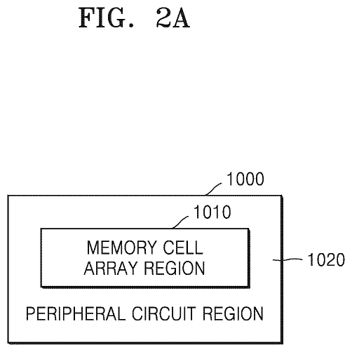

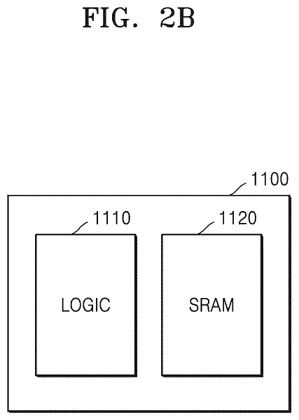

FIGS. 2A and 2B are conceptual views of integrated circuit devices manufactured according to a method of manufacturing an integrated circuit device, according to some example embodiments.

Referring to FIG. 2A, an integrated circuit device 1000 according to an example embodiment may include a memory cell array region 1010 and a peripheral circuit region 1020 around the memory cell array region 1010.

A memory device may be arranged in the memory cell array region 1010. The memory device may be, for example, Static Random Access Memory (SRAM), Dynamic RAM (DRAM), Magnetic RAM (MRAM), Phase change RAM (PRAM), Resistive RAM (RRAM), Ferroelectric RAM (FeRAM), flash memory, or the like, but example embodiments are not limited thereto.

In the peripheral circuit region 1020, circuit devices configured to operate the memory device in the memory cell array region 1010 may be arranged. The circuit device may be, for example, a read circuit, a write circuit, or the like, but example embodiments are not limited thereto.

According to some example embodiments, patterns, which are arranged in the memory cell array region 1010 and/or the peripheral circuit region 1020, may be formed. For example, at least some of active regions, conductive line patterns, hole patterns, and other configurations arranged in the memory cell array region 1010 and/or the peripheral circuit region 1020 may be formed.

Referring to FIG. 2B, an integrated circuit device 1100 according to an example embodiment may include a logic region 1110 and an SRAM region 1120. Here, the logic region 1110 and the SRAM region 1120 are merely examples. Example embodiments are not limited thereto. The integrated circuit device 1100 may include the logic region 1110 and a region where other memory devices are formed (e.g., a region where DRAM, MRAM, PRAM, RRAM, flash memory, and the like are formed).

The logic region 1110 may be a region where a semiconductor device including various types of individual devices is formed. The individual devices may include various microelectronic devices, for example, a metal-oxide-semiconductor field effect transistor (MOSFET) such as a complementary metal-insulator-semiconductor (CMOS) transistor, an image sensor such as system large scale integration (LSI) or a CMOS imaging sensor (CIS), a micro-electro-mechanical system (MEMS), active elements, passive elements, and/or the like.

According to some example embodiments, patterns arranged in the logic region 1110 and/or the SRAM region 1120 may be formed. For example, at least some of active regions, conductive line patterns, hole patterns, and other configurations arranged in the logic region 1110 and/or the SRAM region 1120 may be formed.

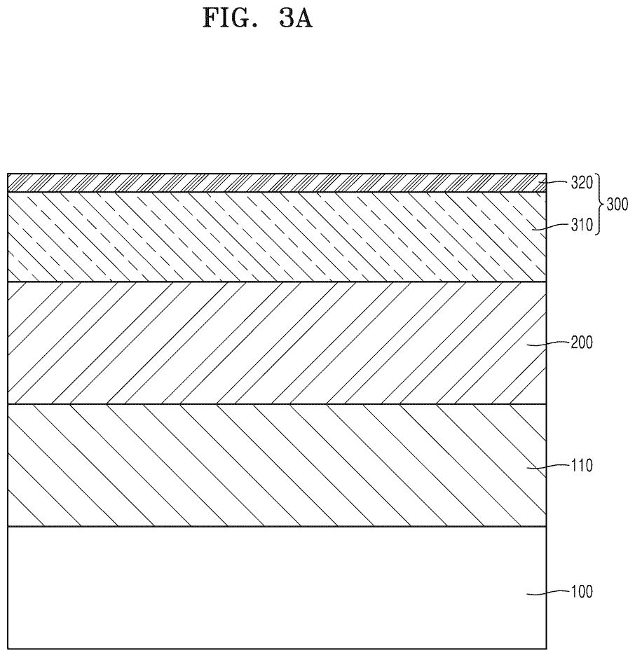

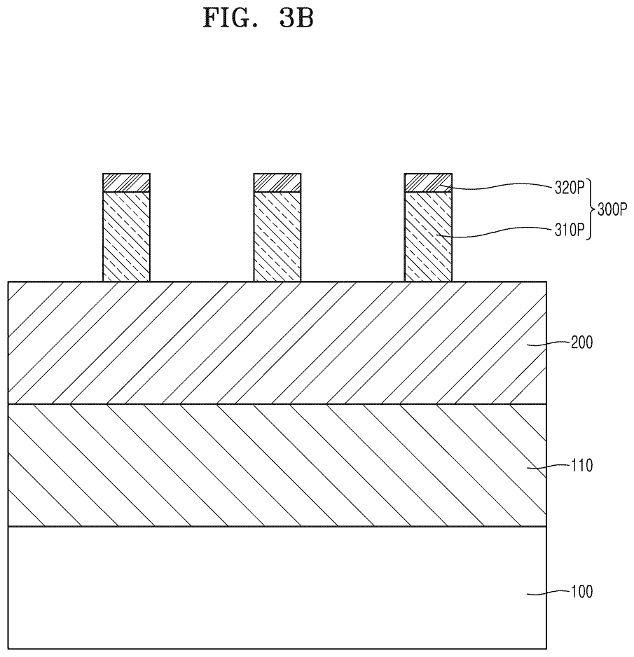

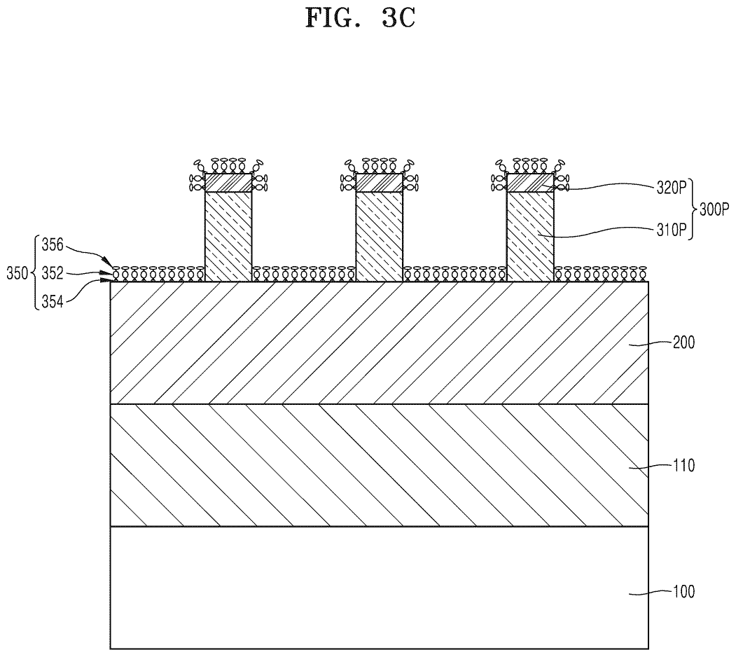

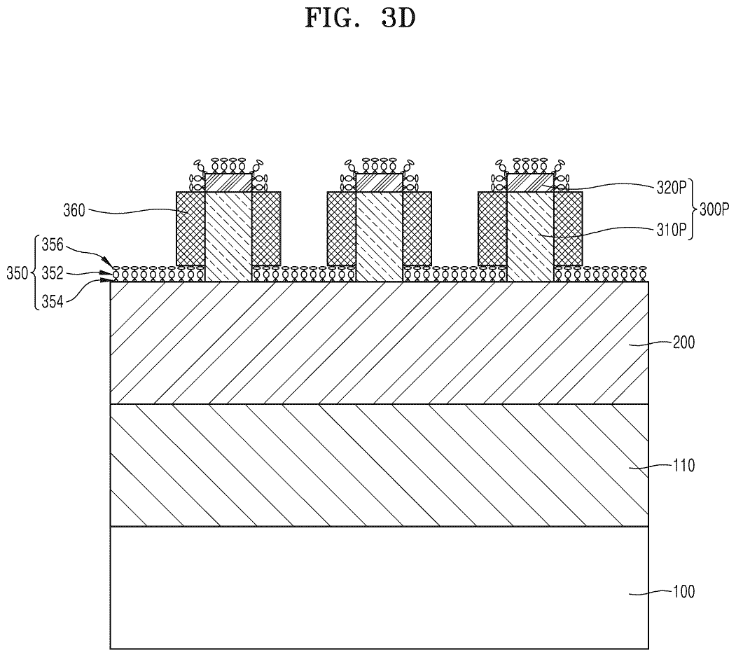

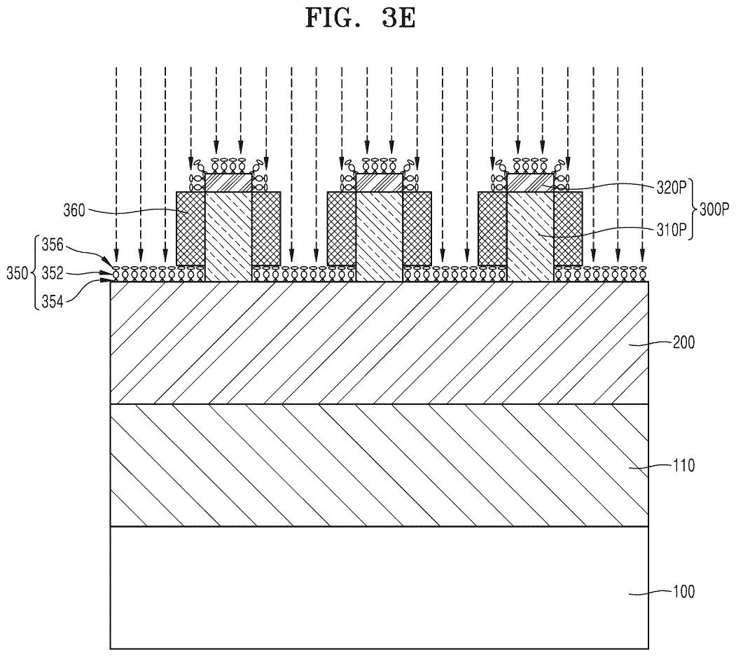

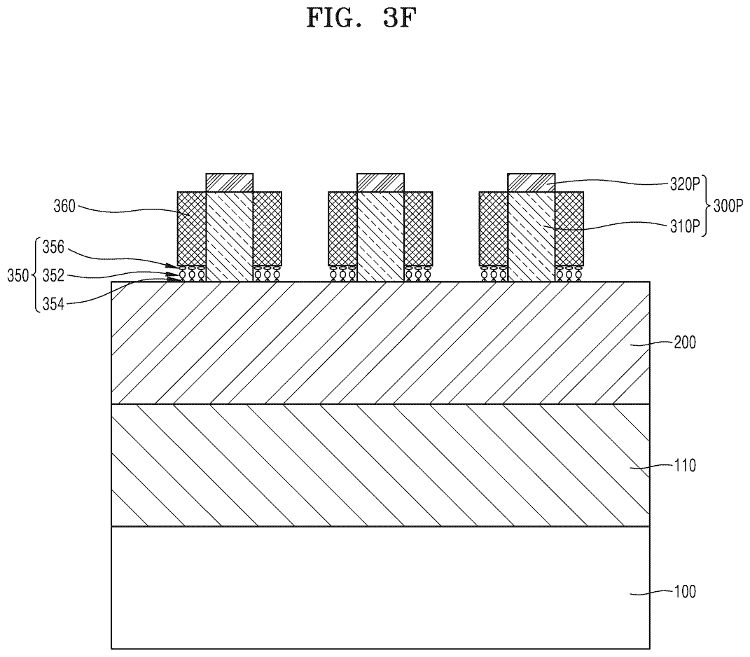

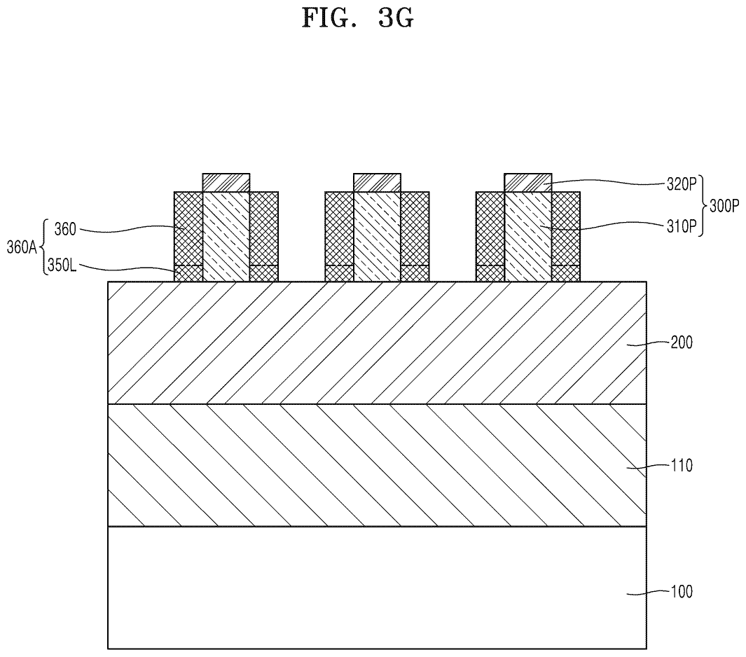

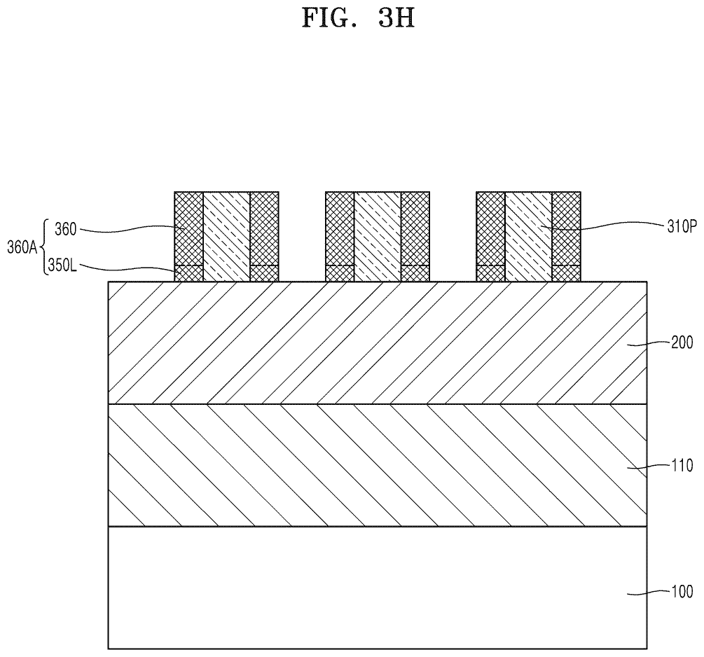

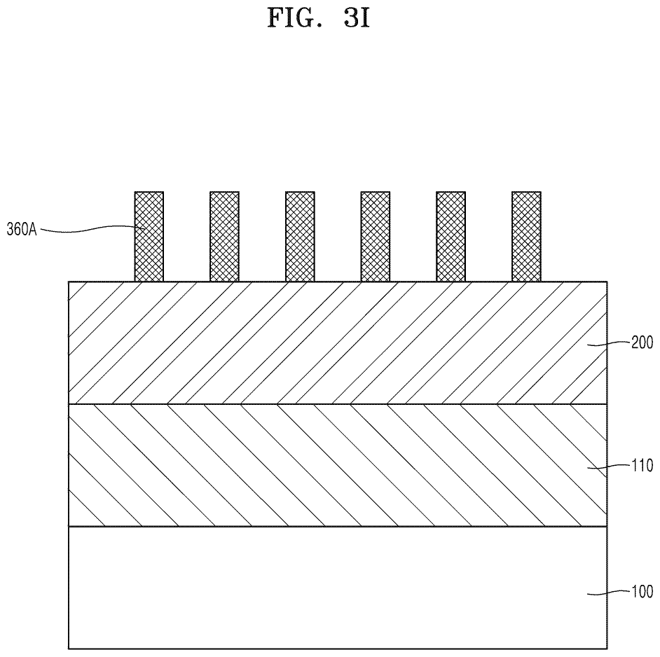

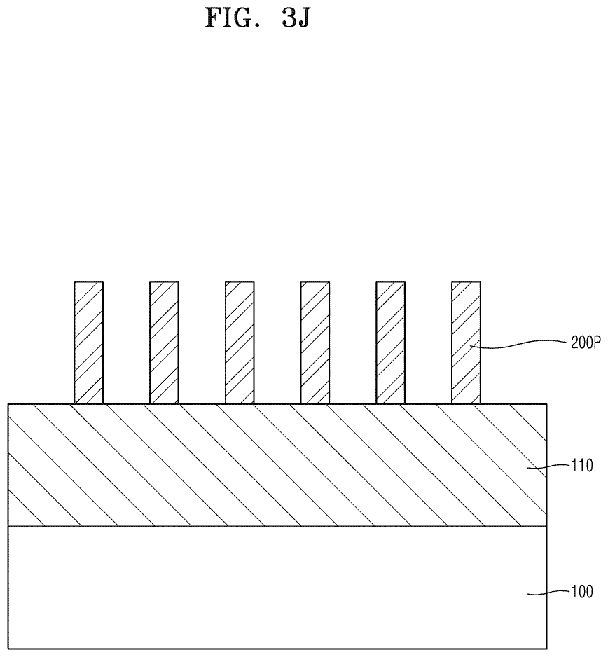

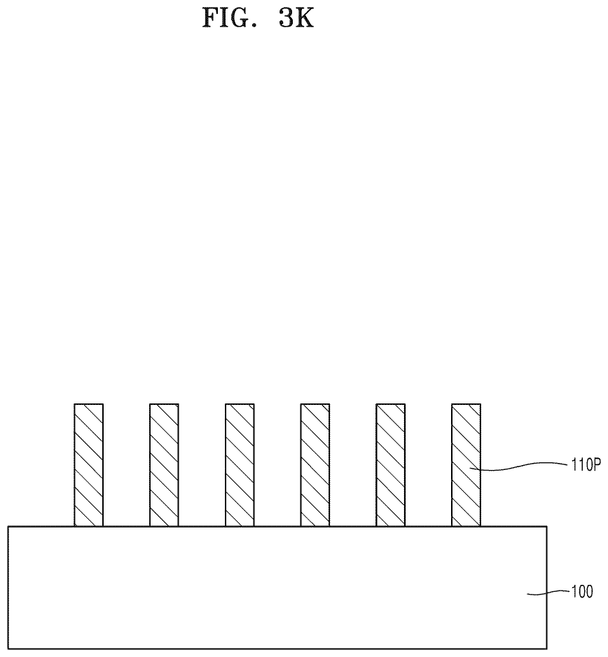

FIGS. 3A to 3K are cross-sectional views illustrating a method of manufacturing an integrated circuit device, according to an example embodiment.

Referring to FIG. 3A, a target layer 110, a base layer 200, and a preliminary mandrel layer 300 are sequentially formed on a substrate 100.

The substrate 100 may include a semiconductor substrate. In some example embodiments, the semiconductor substrate may include semiconductor materials such as group IV semiconductor materials, group III-V semiconductor materials, group II-VI semiconductor materials, or II-VI oxide semiconductor materials. The group IV semiconductor material may include, for example, silicon (Si), germanium (Ge), or Si—Ge. The group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The group II-VI semiconductor material may include, for example, zinc telluride (ZnTe) or cadmium sulfide (Cds). The substrate 100 may be supplied as a bulk wafer or an epitaxial layer. In some example embodiments, the substrate 100 may include a silicon-on-insulator (SOI) substrate or a germanium-on-insulator (GeOI) substrate.

The target layer 110 may include a semiconductor material, a conductive material, or an insulating material. In some example embodiments, the target layer 110 may include a semiconductor material, and portions of the target layer 110 may become active regions. For example, the target layer 110 may be an upper portion of the substrate 100. For example, the target layer 110 may be a semiconductor material layer formed on the substrate 100 by epitaxy. In some example embodiments, the target layer 110 may include a conductive material, and portions of the target layer 110 may become conductive lines. In some example embodiments, the target layer 110 may include an insulating material, and portions of the target layer 110 are removed. and thus, holes may be formed.

The base layer 200 may include a material having etch selectivity relative to the target layer 110. For example, when the target layer 110 includes a conductive material or an insulating material, the base layer 200 may include a semiconductor material such as Si. For example, when the target layer 110 includes a semiconductor material such as Si, the base layer 200 may include an insulating material that contains Si elements such as silicon oxynitride (SiON) or silicon oxide (SiO₂). The base layer 200 also may be referred to as a hard mask layer.

At least some portions of the preliminary mandrel layer 300 may include a material having etch selectivity relative to the base layer 200. For example, at least some portions of the preliminary mandrel layer 300 may include a material that contains carbon (C). The preliminary mandrel layer 300 may have a stack structure including a mandrel base layer 310 and a mandrel hard mask layer 320. The mandrel hard mask layer 320 may have a thickness less than that of the mandrel base layer 310. The mandrel base layer 310 and the mandrel hard mask layer 320 may include different materials. In some example embodiments, the mandrel base layer 310 may include a material containing C, and the mandrel hard mask layer 320 may include a material that does not contain C. For example, the mandrel hard mask layer 320 may include a material that does not contain C but contains Si elements. In some example embodiments, the mandrel base layer 310 may include an Amorphous Carbon Layer (ACL) or a Carbon-based Spin On Hardmask (C-SOH). In some example embodiments, each of the mandrel hard mask layer 320 and the base layer 200 may include a material that does not contain C but contains Si elements. For example, the mandrel hard mask layer 320 may include an insulating material such as SiON or SiO₂.

Referring to FIGS. 3A and 3B together, the preliminary mandrel layer 300 is patterned to form a plurality of mandrel patterns 300P. Each of the mandrel patterns 300P may have a stack structure that includes a mandrel base pattern 310P, which is a portion of the mandrel base layer 310, and a mandrel hard mask pattern 320P, which is a portion of the mandrel hard mask layer 320. In some example embodiments, the mandrel patterns 300P may be formed by patterning the preliminary mandrel layer 300 through Extreme Ultraviolet (EUV) Lithography. In some example embodiments, the mandrel patterns 300P may be formed by patterning the preliminary mandrel layer 300 by using a plurality of hard mask patterns as etch masks, wherein the hard mask patterns are formed by multi-patterning technologies such as Double Patterning Technology (DPT).

In some example embodiments, the surfaces of the base layer 200, the mandrel base pattern 310P, and the mandrel hard mask pattern 320P may each be hydrophilic.

Referring to FIG. 3C, the base layer 200 and the mandrel patterns 300P are exposed to the PIs 350 such that the PIs 350 are attached to the surface of the base layer 200 and the surface of the mandrel hard mask pattern 320P of each mandrel pattern 300P. In some example embodiments, before being exposed to the PIs 350, the surface of the mandrel base pattern 310P may be reduced to become hydrophobic. For example, the oxidized surface of the mandrel base pattern 310P may be reduced to become hydrophobic through surface treatment using H radicals. Each of the surface of the base layer 200 and the surface of the mandrel hard mask pattern 320P may remain hydrophilic. The PIs 350 may be attached to the surface of the base layer 200 and the surface of the mandrel hard mask pattern 320P, both of which are hydrophilic, and may not be attached to the surface of the mandrel base pattern 310P that is hydrophobic.

For example, the PI 350 may be an organo-metallic precursor that includes a moiety capable of suppressing chemical bonding. The PI 350 includes a central element 352, a first ligand 354 bonded to the central element 352, and a second ligand 356. In some example embodiments, the central element 352 may be at least one metal element containing metal atoms, metallic ions, metal compounds, metal alloys, or any combination thereof. For example, the central element 352 may be titanium (Ti), zirconium (Zr), or hafnium (Hf). The first ligand 354 may be referred to as the bonding moiety, and the second ligand 356 may be referred to as the inhibition moiety. In some example embodiments, the first ligand 354 may be an alkoxy ligand, and the second ligand 356 may be a cyclopentadienyl-ligand, but example embodiments are not limited thereto. For example, the first ligand 354 may be a methoxy (—OCH3) ligand. For example, when the central element 352 includes Ti, the PI 350 may be trimethoxy-(pentamethylcyclopentadienyl)-titanium, Cp(CH₃)₅Ti(OMe)₃ (TMPMCT), but is not limited thereto. For example, when the central element 352 includes Zr, the PI 350 may be cyclopentadienyl tris(dimethylamino) zirconium, CpZr(NMe₂)₃ (CpTDMAZ), but is not limited thereto. For example, when the central element 352 includes Hf, the PI 350 may be cyclopentadienyl tris(dimethylamino) hafnium, CpHf(NMe₂)₃ (CPTDMAH), but is not limited thereto. The second ligand 356 may have a structure, for example, a linear carbon chain or an aromatic ring, which is chemically stable and has a specific length and area, thus inhibiting reactions occurring between the precursor and the surface. The abbreviation “Me” refers to a methyl group, “Et” to an ethyl group, “Cp” to cyclopentadienyl, “Pr” to a propyl group, “iPr” to an isopropyl group, “Bu” to a butyl group, “tBu” to a tert-butyl group (1,1-dimethylethyl), and “thd” to 2,2,6,6-tetramethyl heptanedionate.

The first ligands 354 of the PIs 350 may be attached to the surfaces of the base layer 200 and the mandrel hard mask pattern 320P. For example, the first ligands 354 of the PIs 350 may be attached to the surfaces of the base layer 200 and the mandrel hard mask pattern 320P, both of which are hydrophilic, but may not be attached to the surface of the mandrel base pattern 310P that is hydrophobic. The PIs 350 may be attached to the surfaces of the base layer 200 and the mandrel hard mask pattern 320P as a monolayer. For example, other PIs 350 may not be attached to the PIs 350 already attached to the surfaces of the base layer 200 and the mandrel hard mask pattern 320P. In some example embodiments, at least some of the first ligands 354 in some of the PIs 350 may be converted to OH and thus may chemically bond with the base layer 200 and/or the mandrel hard mask pattern 320P.

Referring to FIG. 3D, the side surface spacer layer 360 is formed on the surface of the mandrel base pattern 310P. The side surface spacer layer 360 may include an insulating material that includes oxide, nitride, or metal oxide. For example, the side surface spacer layer 360 may include titanium oxide (TiO₂), hafnium oxide (HfO₂), zirconium oxide (ZrO₂), silicon oxide (SiO₂), or silicon nitride (SiN). In some example embodiments, when the side surface spacer layer 360 includes metal oxide, the metal elements included in the side surface spacer layer 360 may be the same as the central elements of the PIs 350. However, example embodiments are not limited thereto. For example, when the side surface spacer layer 360 includes metal oxide, the metal elements in the side surface spacer layer 360 may be different from the central elements of the PIs 350. In some example embodiments, when the side surface spacer layer 360 includes an insulating material instead of metal oxide, the central elements of the PIs 350 may be different from the elements in the side surface spacer layer 360. The side surface spacer layer 360 may be formed by injecting a spacer deposition precursor and a reactant onto the base layer 200 and the mandrel patterns 300P. In some example embodiments, the side surface spacer layer 360 may be formed by performing Atomic Layer Deposition (ALD) using the spacer deposition precursor. For example, the spacer deposition precursor may include tetrakis dimethylamino titanium (TDMAT), titanium tetrachloride (TiCl₄), tetrakis dimethylamido hafnium (TDMAHf), HfCl₄, tetrakis dimethylamido zirconium (TDMAZr), ZrCl₄, chlorosilanes, aminosilanes, silvamines, or silanes. The reactant is limited to a gas, which does not react with the second ligands 356 of the Pis 350 but reacts with the spacer deposition precursor, to reduce or prevent the deposition reaction in the area including the PIs 350. For example, in the process of forming the side surface spacer layer 360, plasma that contains O₃ or O and provides highly reactive O radicals is excluded, and H₂O reacting with the spacer deposition precursor may be used as the reactant. In other words, in the process of forming the side surface spacer layer 360, instead of plasma containing O₃ or O and providing highly reactive O radicals, H₂O reacting with the spacer deposition precursor may be used as the reactant.

The side surface spacer layer 360 may be formed only on the surface of the mandrel base pattern 310P, but may not be formed on the surfaces of the base layer 200 and the mandrel hard mask pattern 320P. For example, the side surface spacer layer 360 may be formed on the surface of the mandrel base pattern 310P to which the PIs 350 are not attached, but may not be formed on the surfaces of the base layer 200 and the mandrel hard mask pattern 320P to which the PIs 350 are attached. For example, the upper surface of the base layer 200 and the lower surface of the side surface spacer layer 360 may be spaced apart from each other with the PIs 350 therebetween.

In some example embodiments, before the side surface spacer layer 360 is formed, a preprocessing process of flowing H₂O onto the base layer 200 and the mandrel patterns 300P may be performed. In some example embodiments, to form the side surface spacer layer 360, H₂O may also be injected along with the spacer deposition precursors onto the base layer 200 and the mandrel patterns 300P. When H₂O is supplied onto the base layer 200 and the mandrel patterns 300P, the surface of the mandrel base pattern 310P becomes hydrophilic, and thus, the growth rate of the side surface spacer layer 360 may increase. When H₂O is supplied onto the base layer 200 and the mandrel patterns 300P, the first ligands 354 may be removed without substantially affecting the second ligands 356 of the PIs 350 that are the inhibition moieties, and the PIs 350 may chemically bond with the base layer 200. For example, when the first ligand 354 is a methoxy (—OCH₃) ligand, the methyl group may be removed when H₂O is supplied, and the first ligand 354 may chemically bond with the base layer 200. After the methyl group is removed from the PIs 350, a moiety that does not chemically bond with the base layer 200 may be OH-terminated.

Referring to FIGS. 3E and 3F together, some of the PIs 350 are removed. In some example embodiments, some of the PIs 350 may be removed through Atomic Layer Etching (ALE). For example, some of the PIs 350, which are not positioned between the upper surface of the base layer 200 and the lower surface of the side surface spacer layer 360—that is, the PIs 350 attached to a portion of the upper surface of the base layer 200 where the side surface spacer layer 360 is not located and the PIs 350 attached to the surface of the mandrel hard mask pattern 320P—may be removed, while the PIs 350 positioned between the upper surface of the base layer 200 and the lower surface of the side surface spacer layer 360 may remain.

Referring to FIGS. 3F and 3G together, the PIs 350 arranged between the upper surface of the base layer 200 and the lower surface of the side surface spacer layer 360 may be converted into a spacer bonding layer 350L, thus forming a plurality of spacer patterns 360A each having a stack structure including the spacer bonding layer 350L and the side surface spacer layer 360. The spacer bonding layer 350L may be arranged between the upper surface of the base layer 200 and the lower surface of the side surface spacer layer 360, thus bonding the base layer 200 to the side surface spacer layer 360. The spacer bonding layer 350L may be a monolayer. The spacer patterns 360A may cover portions of the upper surface of the base layer 200, which are adjacent to the mandrel patterns 300P, and the side surfaces of the mandrel base pattern 310P of each mandrel pattern 300P. When the central elements of the material forming the side surface spacer layer 360 are the same as those of the PIs 350, the spacer bonding layer 350L of the spacer pattern 360A may be formed integrally with the side surface spacer layer 360. In other words. The spacer pattern 360A may be an integral structure of the spacer bonding layer 350L and the side surface spacer layer 360. The spacer pattern 360A may include metal oxide. For example, the spacer pattern 360A may include TiO₂, HfO₂, or ZrO₂.

In some example embodiments, the second ligands 356 of the PIs 350 are removed through treatment using oxygen (O) radicals, and thus, the PIs may be converted into the spacer bonding layer 350L. For example, by supplying ozone (O₃) or plasma that includes oxygen radicals (O₂, H₂O, N₂O, CO₂, or NO) on the base layer 200 on which the mandrel patterns 300P and the side surface spacer layers 360 are formed, the PIs 350 may be converted into the spacer bonding layer 350L.

Referring to FIGS. 3G and 3H together, the upper surfaces of the mandrel base patterns 310P are exposed by removing the mandrel hard mask patterns 320P. The mandrel hard mask patterns 320P may be removed through etching.

Referring to FIGS. 3H and 3I together, the mandrel base patterns 310P are removed, leaving the spacer patterns 360A on the base layer 200. The mandrel base patterns 310P may be removed by ashing and/or stripping.

Referring to FIGS. 3I and 3J together, the base layer 200 is patterned using the spacer patterns 360A as etch masks, and thus, the base patterns 200P are formed. The base patterns 200P may be referred to as hard mask patterns.

Referring to FIGS. 3J and 3K together, the target layer 110 is patterned using the base patterns 200P as etch masks, thereby forming a plurality of target patterns 110P. For example, the target patterns 110P may be a plurality of active regions or a plurality of conductive line patterns. In some example embodiments, the target patterns 110P may define a plurality of hole patterns.

Referring to FIGS. 3A to 3K together, the base patterns 200P and the target patterns 110P may be patterned using the spacer patterns 360A formed to cover the side surfaces of the mandrel base patterns 310P.

For example, when spacer patterns are formed on the base layer 200 by first forming a spacer layer, which conformally covers the base layer 200 and the mandrel patterns 300P, and then anisotropically etching the spacer layer and removing the mandrel patterns 300P, the spaces between the spacer patterns may be formed to have depths that are different from the depths of the spaces where the mandrel patterns 300P were located and the depths of the spaces where the mandrel patterns 300P were not located. Therefore, when the base patterns 200P are formed by patterning the base layer 200 by using the spacer patterns as etch masks, defects may occur, wherein the defects include a decrease in the uniformity of the base patterns 200P or the collapse of some of the base patterns 200P.

However, because the spacer patterns 360A are formed to cover only the side surfaces of the mandrel base patterns 310P, the spaces between the spacer patterns 360A may be formed to have depths that are the same as or substantially similar to each other, regardless of whether the mandrel patterns 300P are present. Therefore, the base patterns 200P and the target patterns 110P, which are patterned using the spacer patterns 360A, may have improved uniformity.

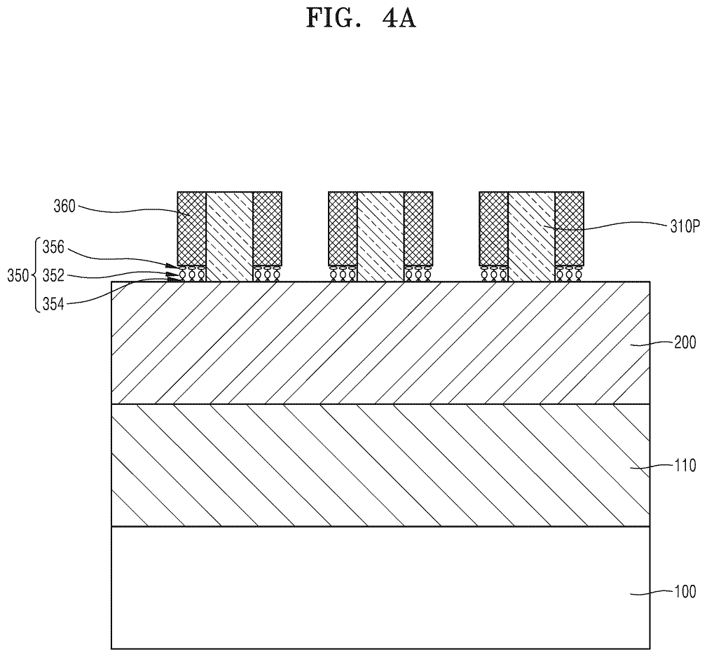

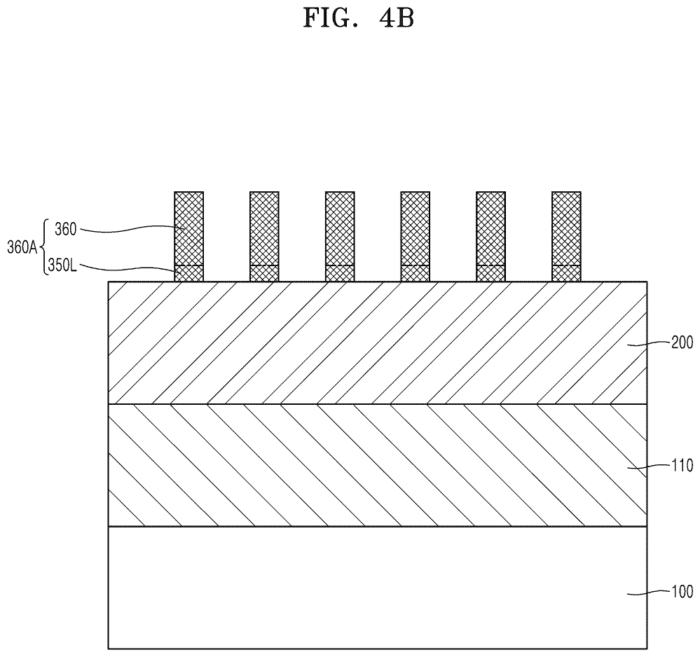

FIGS. 4A and 4B are cross-sectional views illustrating a method of manufacturing an integrated circuit device, according to an example embodiment.

Referring to FIGS. 3F and 4A together, the upper surfaces of the mandrel base patterns 310P are exposed by removing the mandrel hard mask patterns 320P. The mandrel hard mask patterns 320P may be removed through etching.

Referring to FIGS. 4A and 4B together, the PIs 350, which are arranged between the upper surface of the base layer 200 and the lower surface of the side surface spacer layer 360, may be changed to the spacer bonding layer 350L, thereby forming the spacer patterns 360A each having a stack structure of the spacer bonding layer 350L and the side surface spacer layer 360. For example, the PIs 350 may be changed to the spacer bonding layer 350L through O radical treatment. During the O radical treatment for converting the PIs 350 into the spacer bonding layer 350L, the mandrel base patterns 310P are removed as well such that the spacer patterns 360A may remain on the base layer 200. Then, referring to FIGS. 3J and 3K together, the base patterns 200P and the target patterns 110P may be formed.

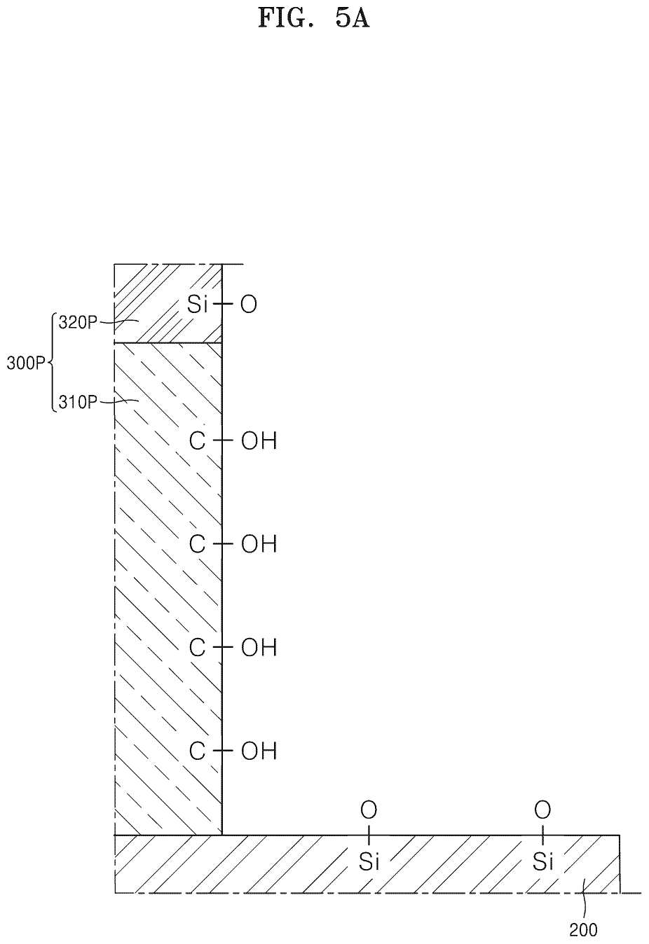

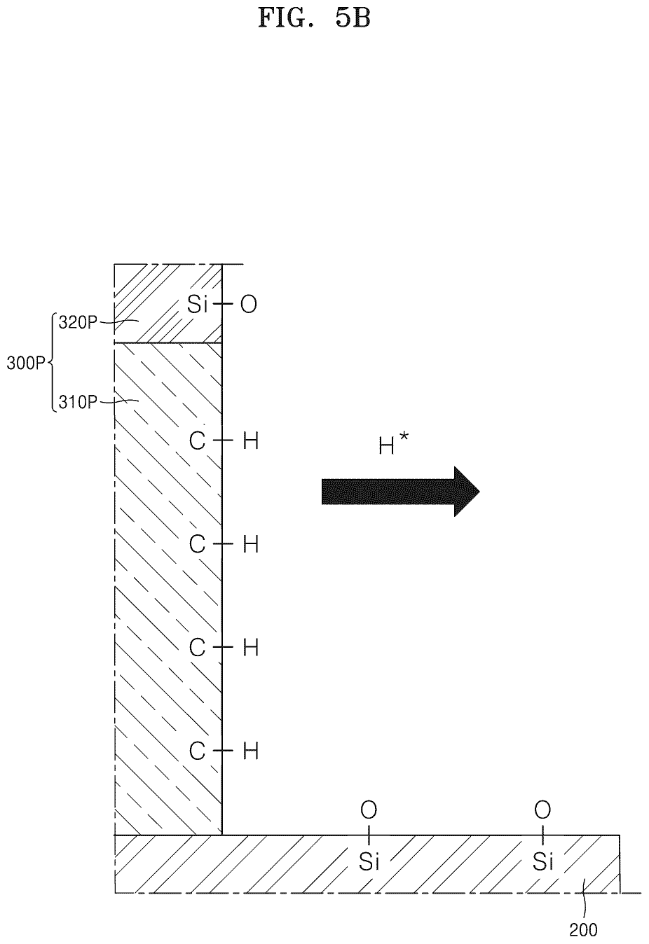

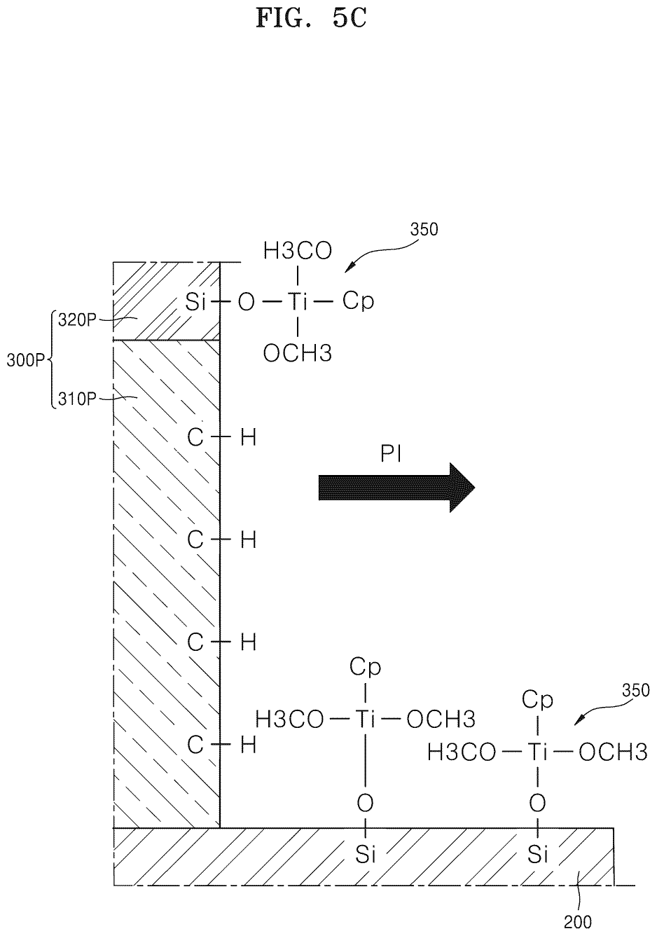

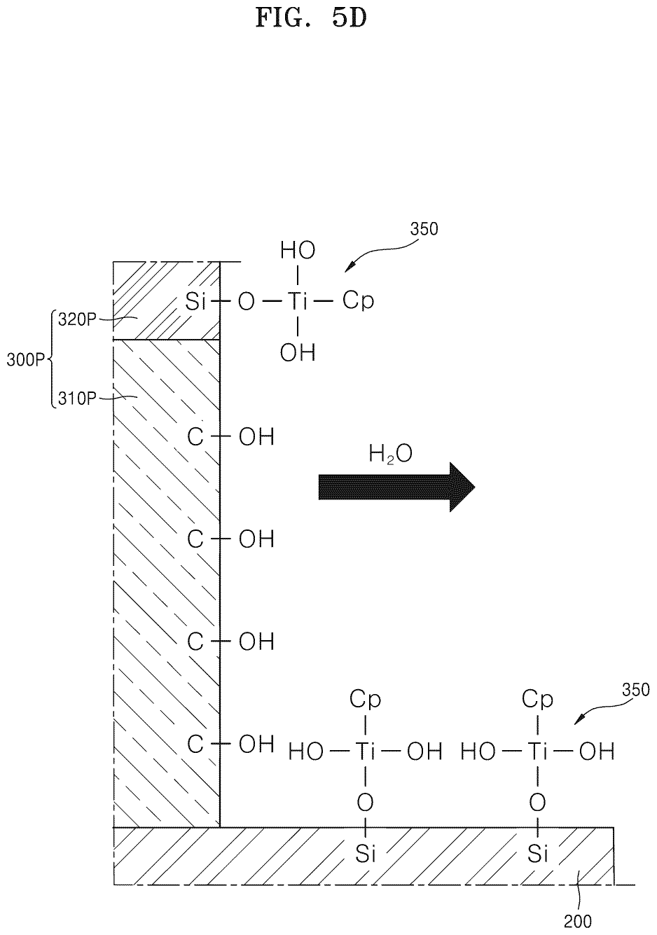

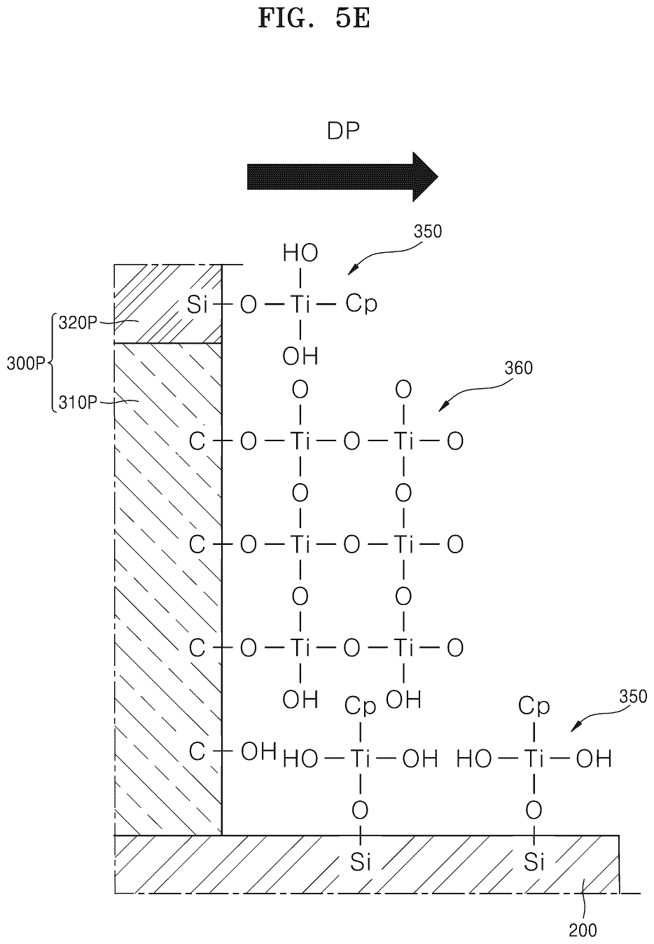

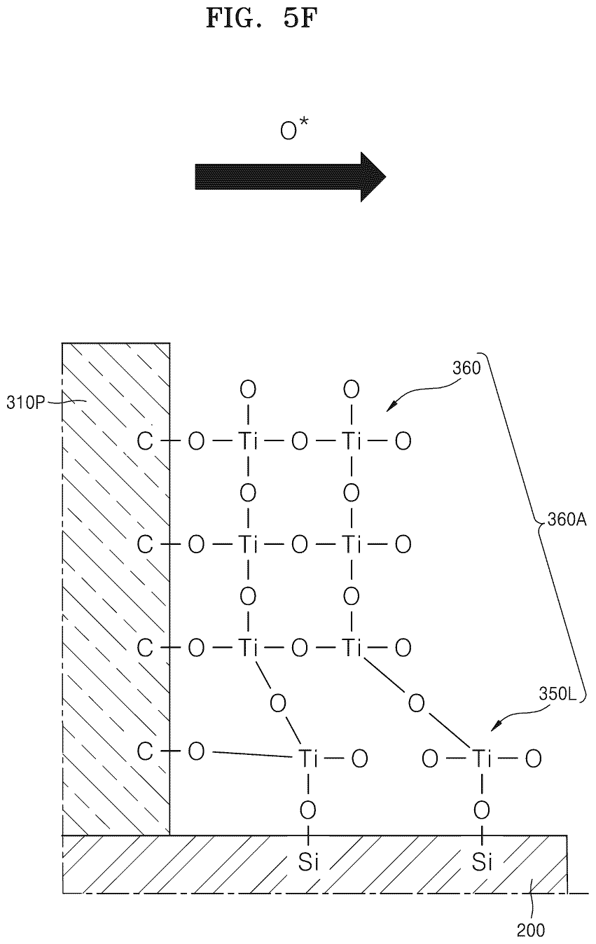

FIGS. 5A to 5F are conceptual views for describing a method of manufacturing an integrated circuit device, according to an example embodiment. In detail, FIGS. 5A to 5F illustrate a method of manufacturing an integrated circuit device in a case where the PI 350 of FIG. 3C include TMPMCT and the side surface spacer layer 360 of FIG. 3D and the spacer pattern 360A of FIG. 3G include TiO₂.

Referring to FIG. 5A together with FIG. 3B, the plurality of mandrel patterns 300P, each of which has a stack structure including the mandrel base pattern 310P and the mandrel hard mask pattern 320P, are formed on the base layer 200. In some example embodiments, the surfaces of the base layer 200, the mandrel base pattern 310P, and the mandrel hard mask pattern 320P may each be hydrophilic. For example, when the base layer 200 and the mandrel hard mask pattern 320P include Si, each of the base layer 200 and the mandrel hard mask pattern 320P may have an oxygen-terminated surface. For example, when the mandrel base pattern 310P includes C, the mandrel base pattern 310P may have a hydroxy-terminated surface.

Referring to FIGS. 5A and 5B together with FIG. 3B, the surface of the mandrel base pattern 310P may be reduced to become hydrophobic through H radical treatment. Each of the surface of the base layer 200 and the surface of the mandrel hard mask pattern 320P may remain hydrophilic. For example, when the mandrel base pattern 310P includes C, the mandrel base pattern 310P may have a hydrogen-terminated surface through H radical treatment.

Referring to FIG. 5C together with FIG. 3C, the surfaces of the base layer 200 and the mandrel patterns 300P are exposed to the PIs 350, and thus, the PIs 350 are attached to the surface of the base layer 200 and the surface of the mandrel hard mask pattern 320P of each mandrel pattern 300P. The PI 350 may be attached to the surface of the base layer 200 and the surface of the mandrel hard mask pattern 320P, both of which are hydrophilic, and may not be attached to the surface of the mandrel base pattern 310P that is hydrophobic.

For example, the PI 350 may be an organo-metallic precursor that includes a moiety capable of suppressing chemical bonding. The PI 350 includes a central element 352, a first ligand 354 bonded to the central element 352, and a second ligand 356. In some example embodiments, the central element 352 may include metal. For example, the central element 352 may include Ti. For example, the PIs 350 may be TMPMCT. The first ligand 354 may be an alkoxy ligand, and the second ligand 356 may be a cyclopentadienyl ligand.

The alkoxy ligands of each TMPMCT may be attached to the surface of the base layer 200 and the surface of the mandrel hard mask pattern 320P. For example, the alkoxy ligands of each TMPMCT may be attached to the surfaces of the base layer 200 and the mandrel hard mask pattern 320P, both of which are hydrophilic, but may not be attached to the surface of the mandrel base pattern 310P, which is hydrophobic. TMPMCTs may be attached to the surfaces of the base layer 200 and the mandrel hard mask pattern 320P as a monolayer. For example, TMPMCT may not adhere to the TMPMCT already attached to the surfaces of the base layer 200 and the mandrel hard mask pattern 320P. In some example embodiments, at least some of the alkoxy ligands of some of TMPMCTs may be converted to OH, and thus, at least some of the TMPMCTs may chemically bond with the base layer 200 and/or the mandrel hard mask pattern 320P.

Referring to FIG. 5D together with FIG. 3D, a preprocessing process of flowing H₂O onto the base layer 200 and the mandrel patterns 300P may be conducted. When H₂O is supplied onto the base layer 200 and the mandrel patterns 300P, the mandrel base pattern 310P may have a hydroxy-terminated surface; thus, the surface of the mandrel base pattern 310P may become hydrophilic. When H₂O is supplied onto the base layer 200 and the mandrel patterns 300P, the alkoxy ligands in TMPMCT may be changed to OH. Hereafter, TMPMCT may refer to the state in which the alkoxy ligands are converted to OH and chemically bond with the base layer 200 and the mandrel hard mask patterns 320P.

Referring to FIG. 5E together with FIG. 3D, a spacer deposition precursor DP is injected onto the base layer 200 and the mandrel patterns 300P, thus forming the side surface spacer layer 360. In some example embodiments, for example, the side surface spacer layer 360 may include TiO₂. In some example embodiments, the side surface spacer layer 360 may be formed through ALD using the DP. For example, the DP may include TDMAT, TiCl₄, titanium tetrakis(isopropoxide) (Ti(O-iPr)₄), cyclopentadienyl titanium, titanium bis(isopropoxide)bis(2,2,6,6-tetramethyl-3,5-heptanedionate) (Ti(O-iPr)₂(thd)₂), tetrakis(diethylamino)titanium (TEMAT, (Et₂N)₄Ti), trimethoxy(pentamethylcyclopentadienyl)titanium ((Cp*)Ti(OMe)₃), or any derivatives thereof, but is not limited thereto. In some example embodiments, when the side surface spacer layer 360 includes HfO₂, the DP may include TDMAHf, HfCl₄, Hf(iPr)(NMe₂)₃, HfCp₂Me₂, Hf(OtBu)₄, Hf(OEt)₄, Hf(NEt₂)₄, Hf(NMe₂)₄, Hf(NMeEt)₄, Hf(thd)₄ (where, thd=2,2,6,6,-tetramethyl-3,5-heptanedionate) or any derivatives thereof, but is not limited thereto.

The side surface spacer layer 360 may be formed only on the surface of the mandrel base pattern 310P, but may not be formed on the surfaces of the base layer 200 and the mandrel hard mask pattern 320P. For example, the side surface spacer layer 360 may be formed on the surface of the mandrel base pattern 310P, to which TMPMCT does not adhere, but may not be formed on the surfaces of the base layer 200 and the mandrel hard mask pattern 320P where TMPMCT adhere and cyclopentadienyl ligands are exposed. For example, the upper surface of the base layer 200 and the lower surface of the side surface spacer layer 360 may be spaced apart from each other with the cyclopentadienyl ligands therebetween.

In some example embodiments, instead of injecting H₂O onto the base layer 200 and the mandrel patterns 300P before the side surface spacer layer 360 of FIG. 5D is formed, H₂O may be injected along with the DP to form the side surface spacer layer 360 of FIG. 5E.

When H₂O is supplied onto the base layer 200 and the mandrel patterns 300P, the surface of the mandrel base pattern 310P becomes hydrophilic, and thus, the growth rate of the side surface spacer layer 360 may increase.

Referring to FIGS. 5E and 5F together with FIG. 3G, TMPMCT between the upper surface of the base layer 200 and the lower surface of the side surface spacer layer 360 is converted into the spacer bonding layer 350L, thereby forming the spacer patterns 360A each having a stack structure including the spacer bonding layer 350L and the side surface spacer layer 360. The spacer bonding layer 350L may be a monolayer. The spacer patterns 360A may cover portions of the upper surface of the base layer 200, which are adjacent to the mandrel patterns 300P, and the side surfaces of the mandrel base pattern 310P of each mandrel pattern 300P. When the central elements of the material forming the side surface spacer layer 360 are the same as the central elements of the PIs 350, such as Ti, the spacer bonding layer 350L of the spacer pattern 360A may be formed integrally with the side surface spacer layer 360. In other words, the spacer pattern 360A may be an integral structure of the spacer bonding layer 350L and the side surface spacer layer 360.

In some example embodiments, the cyclopentadienyl ligands in TMPMCT may be removed through O radical treatment, the TMPMCT may be converted into the spacer bonding layer 350L. For example, by supplying O₃ or plasma including O radicals (O₂, H₂O, N₂O, CO₂, or NO) onto the base layer 200 on which the mandrel patterns 300P and the side surface spacer layers 360 are formed, TMPMCT may be converted into the spacer bonding layer 350L.

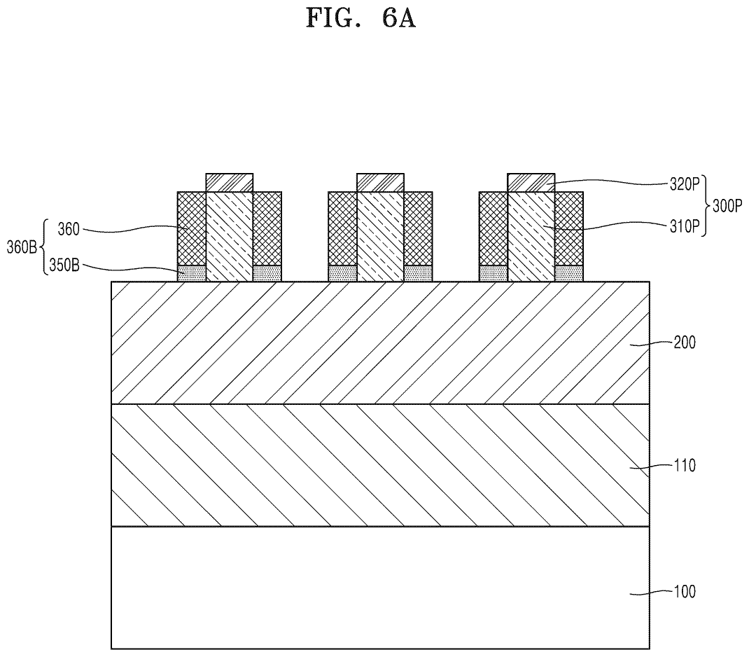

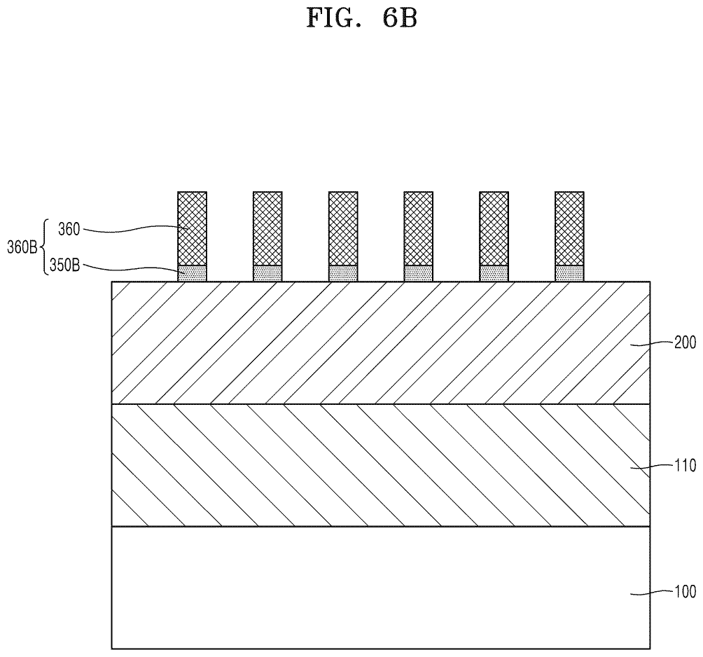

FIGS. 6A and 6B are cross-sectional views illustrating a method of manufacturing an integrated circuit device, according to an example embodiment.

Referring to FIGS. 3F and 6A together, the PIs 350, which are arranged between the upper surface of the base layer 200 and the lower surface of the side surface spacer layer 360, may be changed to a spacer bonding layer 350B, thereby forming a plurality of spacer patterns 360B each having a stack structure of the spacer bonding layer 350B and the side surface spacer layer 360. The spacer bonding layer 350B may be a monolayer. The spacer patterns 360B may cover portions of the upper surface of the base layer 200, which are adjacent to the mandrel patterns 300P, and the side surfaces of the mandrel base pattern 310P of each mandrel pattern 300P. When the central elements of the material forming the side surface spacer layer 360 are different from those of the PIs 350, the spacer pattern 360B may have a stack structure including the spacer bonding layer 350B and the side surface spacer layer 360. When the spacer bonding layer 350B includes TiO₂, the side surface spacer layer 360 may include HfO₂, ZrO₂, SiO₂, or SiN, and when the spacer bonding layer 350B includes HfO₂, the side surface spacer layer 360 may include TiO₂, ZrO₂, SiO₂, or SiN, and when the spacer bonding layer 350B includes ZrO₂, the side surface spacer layer 360 may include TiO₂, HfO₂, SiO₂, or SiN.

In some example embodiments, the second ligands 356 in the PIs 350 may be removed through O radical treatment, and the PIs 350 may be converted into the spacer bonding layer 350B. For example, by supplying O₃ or plasma including O radicals (O₂, H₂O, N₂O, CO₂, or NO) onto the base layer 200 on which the mandrel patterns 300P and the side surface spacer layers 360 are formed, the PIs 350 may be converted into the spacer bonding layer 350B.

Referring to FIGS. 6A and 6B together, the upper surfaces of the mandrel base patterns 310P are exposed by removing the mandrel hard mask patterns 320P. The mandrel hard mask patterns 320P may be removed through etching. Then, the mandrel base patterns 310P are removed, leaving the spacer patterns 360B on the base layer 200. The mandrel base patterns 310P may be removed by ashing and/or stripping. Then, referring to FIGS. 3J and 3K together, the base patterns 200P and the target patterns 110P may be formed.

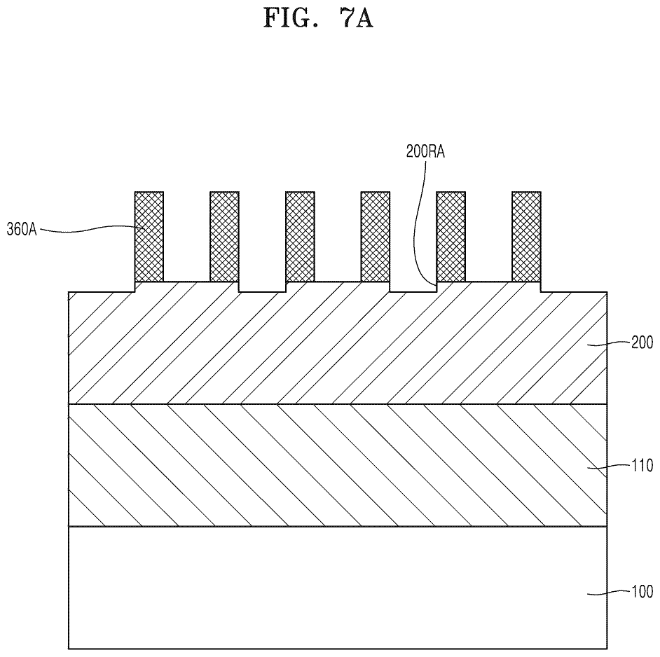

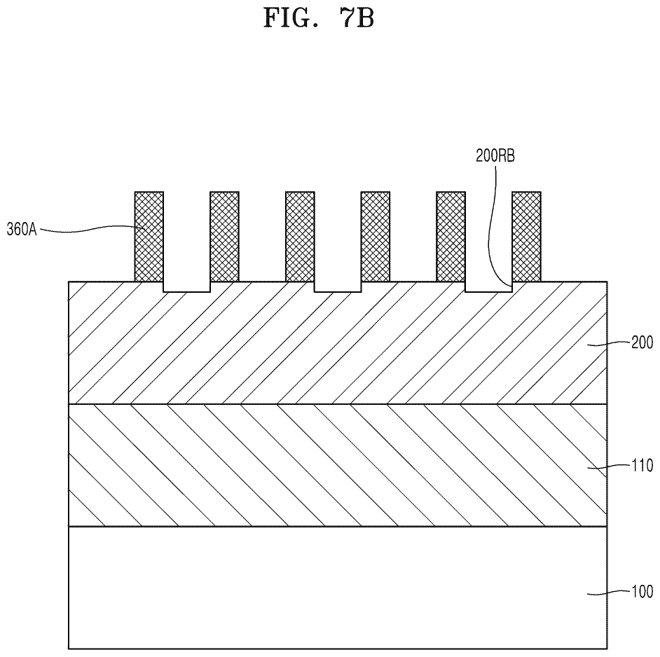

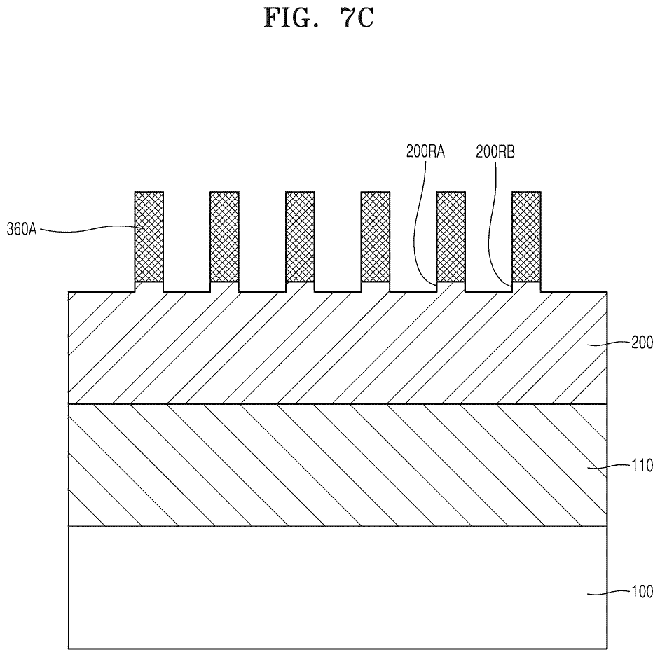

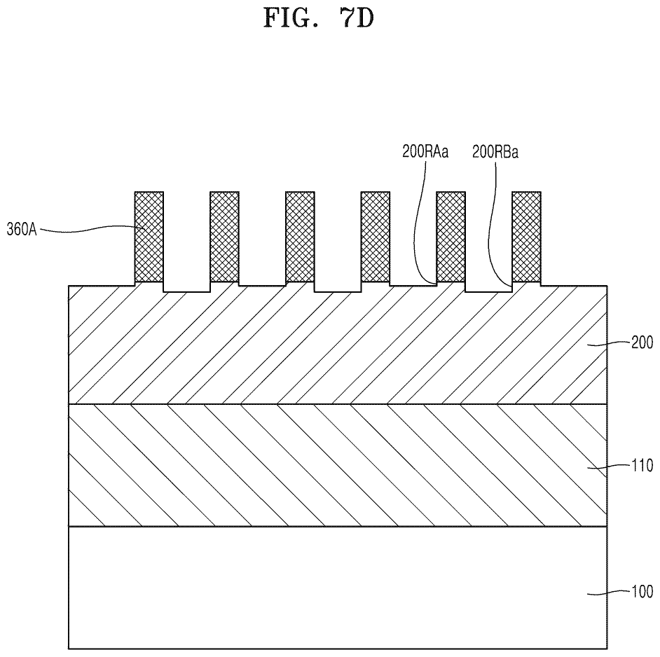

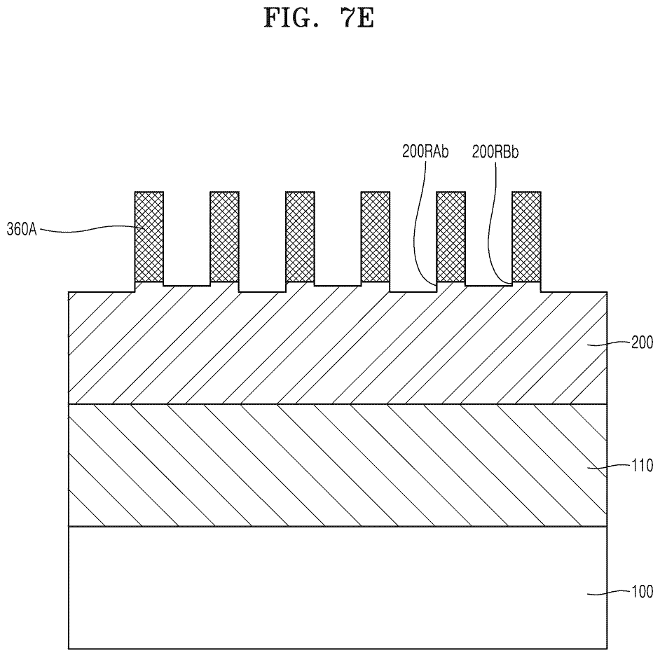

FIGS. 7A to 7E are cross-sectional views illustrating a method of manufacturing an integrated circuit device, according to an example embodiment.

Referring to FIG. 7A, while the mandrel hard mask patterns 320P of FIGS. 3G and 3H are removed, upper portions of the base layer 200 on which the mandrel base patterns 310P are not positioned, are removed. Thus, a plurality of first recesses 200RA may be formed. The first recesses 200RA may be alternately formed or not formed in the spaces between two adjacent mandrel base patterns 310P among the mandrel base patterns 310P. For example, the first recess 200RA may be formed under one of the two spaces between three adjacent mandrel base patterns 310P among the mandrel base patterns 310P, but may not be formed under the other. The bottom surface of the first recess 200RA may be at a lower vertical level than the uppermost surface of the base layer 200.

Referring to FIG. 7B, while the mandrel base patterns 310P of FIGS. 3H and 3I are removed, upper portions of the base layer 200 on the lower portions of the mandrel base patterns 310P may be removed together with the mandrel base patterns 310P such that a plurality of second recesses 200RB may be formed. The second recesses 200RB may be alternately formed or not formed in the spaces between two adjacent mandrel base patterns 310P among the mandrel base patterns 310P. For example, the second recess 200RB may be formed under one of the two spaces between three adjacent mandrel base patterns 310P among the mandrel base patterns 310P, but may not be formed under the other of the two spaces. The bottom surface of the second recess 200RB may be at a lower vertical level than the uppermost surface of the base layer 200.

Referring to FIG. 7C, while the mandrel hard mask patterns 320P of FIGS. 3G and 3H and the mandrel base patterns 310P of FIGS. 3H and 3I are removed, upper portions of the base layer 200 are removed, and thus, the first recesses 200RA of FIG. 7A and the second recesses 200RB of FIG. 7B may be formed. The first recesses 200RA and the second recesses 200RB may be alternately formed in the spaces between the mandrel base patterns 310P. For example, the first recess 200RA may be formed under one of two spaces between three adjacent mandrel base patterns 310P among the mandrel base patterns 310P, and the second recess 200RB may be formed under the other of the two spaces. In some example embodiments, the bottom surface of the first recess 200RA and the bottom surface of the second recess 200RB may each be at a lower vertical level than the uppermost surface of the base layer 200 but may be at the same vertical level.

Referring to FIG. 7D, a plurality of first recesses 200RAa may be formed as upper portions of the base layer 200 are removed during the removal of the mandrel hard mask patterns 320P shown in FIGS. 3G and 3H, and a plurality of second recesses 200RBa may be formed as other upper portions of the base layer 200 are removed during the removal of the mandrel base patterns 310P shown in FIGS. 3H and 3I. The first recesses 200RAa and the second recesses 200RBa may be alternately formed in the spaces between the mandrel base patterns 310P. For example, the first recess 200RAa may be formed under one of two spaces between three adjacent mandrel base patterns 310P among the mandrel base patterns 310P, and the second recess 200RBa may be formed under the other of the two spaces. In some example embodiments, the bottom surface of the first recess 200RAa and the bottom surface of the second recess 200RBa may each be at a lower vertical level than the uppermost surface of the base layer 200, and the bottom surface of the second recess 200RBa may be at a lower vertical level than the bottom surface of the first recess 200RAa.

Referring to FIG. 7E, a plurality of first recesses 200RAb may be formed as upper portions of the base layer 200 are removed during the removal of the mandrel hard mask patterns 320P shown in FIGS. 3G and 3H, and a plurality of second recesses 200RBb may be formed as other upper portions of the base layer 200 are removed during the removal of the mandrel base patterns 310P shown in FIGS. 3H and 3I. The first recesses 200RAb and the second recesses 200RBb may be alternately formed in the spaces between the mandrel base patterns 310P. For example, the first recess 200RAb may be formed under one of two spaces between three adjacent mandrel base patterns 310P among the mandrel base patterns 310P, and the second recess 200RBb may be formed under the other of the two spaces. In some example embodiments, the bottom surface of the first recess 200RAb and the bottom surface of the second recess 200RBb may each be at a lower vertical level than the uppermost surface of the base layer 200, and the bottom surface of the first recess 200RAb may be at a lower vertical level than the bottom surface of the second recess 200RBb.

Referring to FIGS. 7A to 7E together with FIG. 3I, the depths of the spaces between the spacer patterns 360A may be the same as or substantially similar to each other. For example, the first recesses 200RA, 200RAa, and 200RAb, which are formed as upper portions of the base layer 200 are removed during the removal of the mandrel hard mask patterns 320P shown in FIGS. 3G and 3H, and the second recesses 200RB, 200RBa, and 200RBb, which are formed as other upper portions of the base layer 200 are removed during the removal of the mandrel base patterns 310P shown in FIGS. 3H and 3I, may be designed to have a relatively small depth difference, and thus, the base patterns 200P of FIG. 3J and the target patterns 110P of FIG. 3K, which are patterned using the spacer patterns 360A, may have improved uniformity.

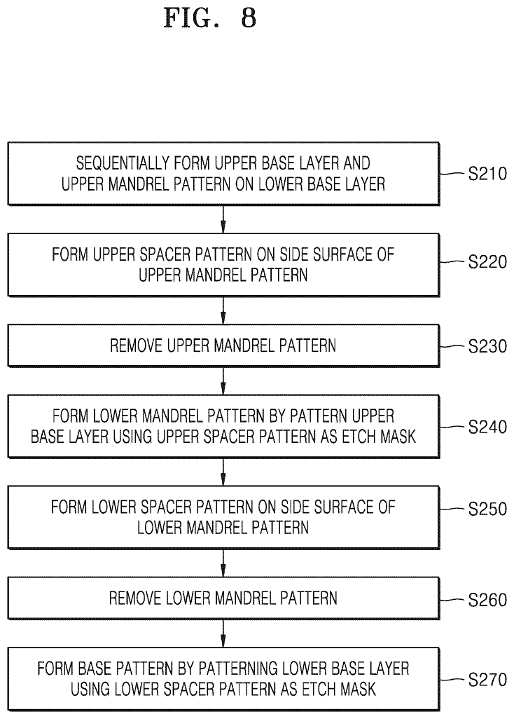

FIG. 8 is a flowchart of a method of manufacturing an integrated circuit device, according to an example embodiment.

Referring to FIG. 8, in operation S210, an upper base layer and an upper mandrel pattern are sequentially formed on a lower base layer. In some example embodiments, the upper mandrel pattern may be formed to have a stack structure including an upper mandrel base pattern and an upper mandrel hard mask pattern. In some example embodiments, the upper mandrel pattern may be a single layer.

In operation S220, after the upper mandrel pattern is formed, upper spacer patterns are formed on side surfaces of the upper mandrel pattern. In some example embodiments, the upper spacer patterns may be formed according to the same method as that used to form the spacer patterns described in operations S120 to S150 of FIG. 1. In some example embodiments, the upper spacer patterns may be formed by first forming an upper spacer layer, which conformally covers the upper base layer and the upper mandrel pattern, and then anisotropically etching the upper spacer layer.

In operation S230, the upper mandrel pattern is removed, leaving the upper spacer patterns on the upper base layer. Then, in operation S240, the upper base layer is patterned using the upper spacer pattern as an etch mask, thus forming a lower mandrel pattern. The lower mandrel pattern may be formed to have a stack structure including a lower mandrel base pattern and a lower mandrel hard mask pattern.

In operation S250, after the lower mandrel pattern is formed, a lower spacer pattern is formed on side surfaces of the lower mandrel pattern. For example, the lower spacer pattern may be formed according to the same method as that used to form the spacer pattern described in operations S120 to S150 of FIG. 1.

In operation S260, the lower mandrel pattern is removed, leaving the lower spacer pattern on the lower base layer. In operation S270, the lower base layer is patterned using the lower spacer pattern as an etch mask, thus forming a base pattern. In some example embodiments, a target layer located on the lower portion of the base pattern may be patterned using the base pattern as an etch mask, thus forming a target pattern.

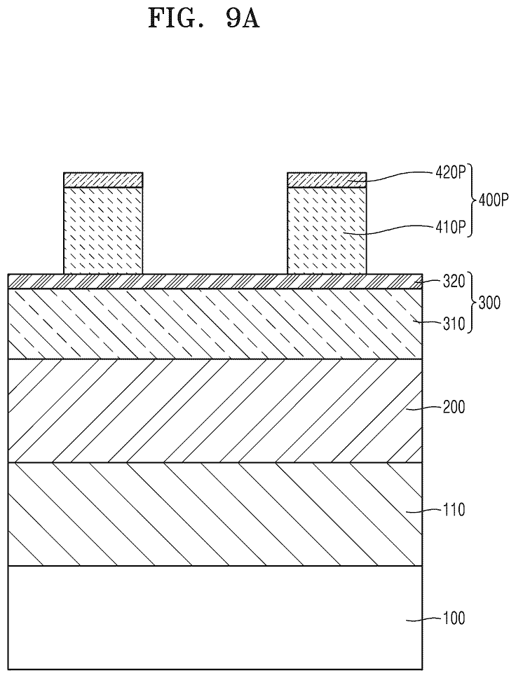

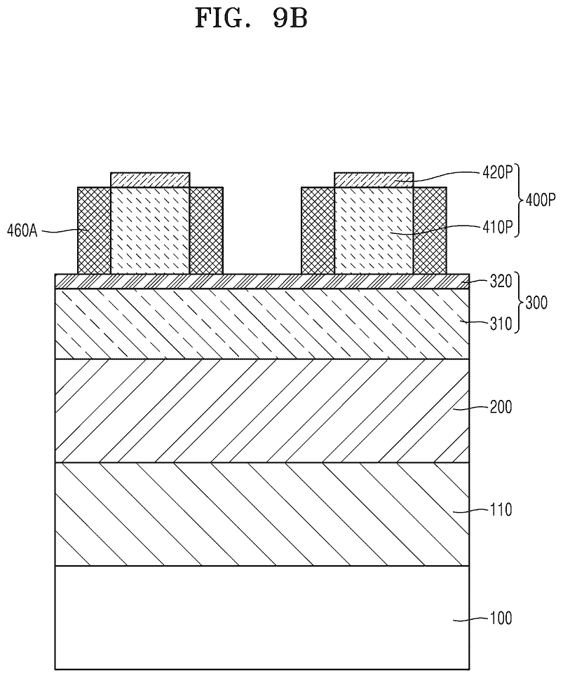

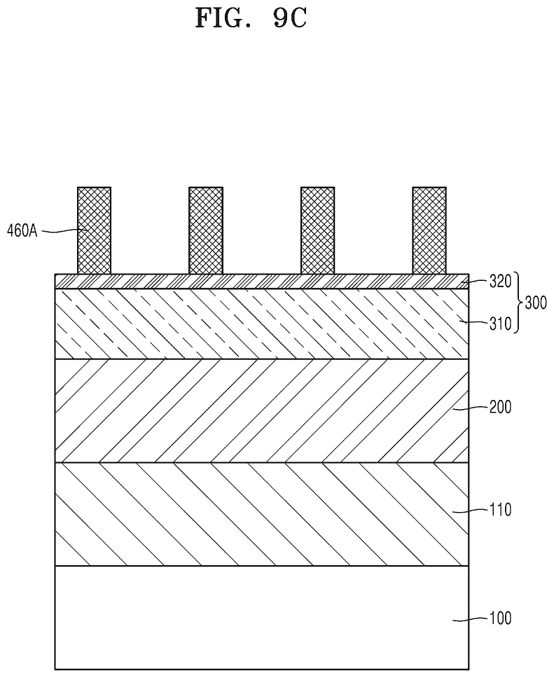

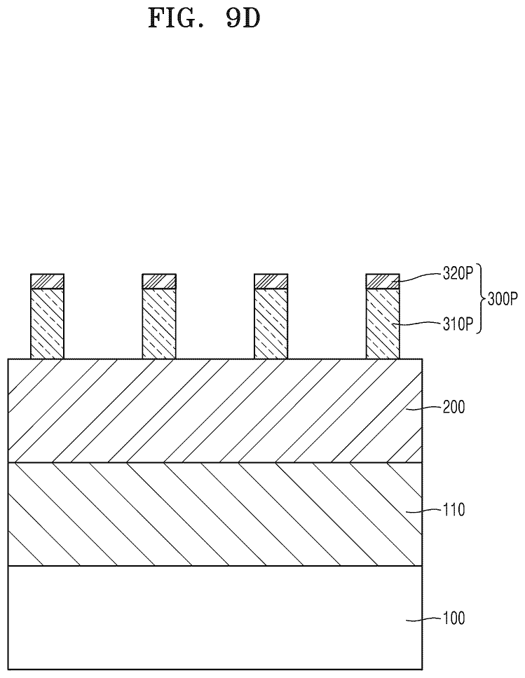

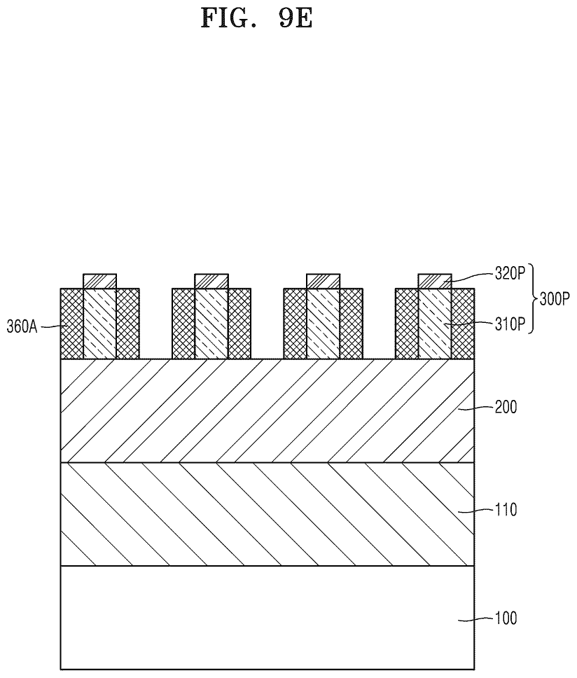

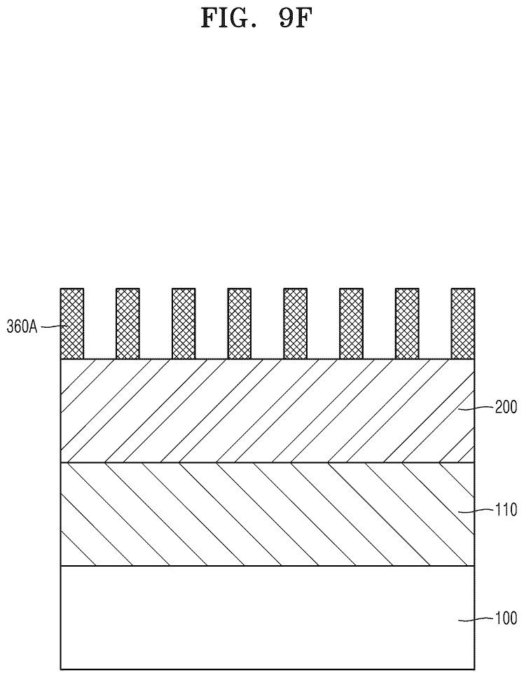

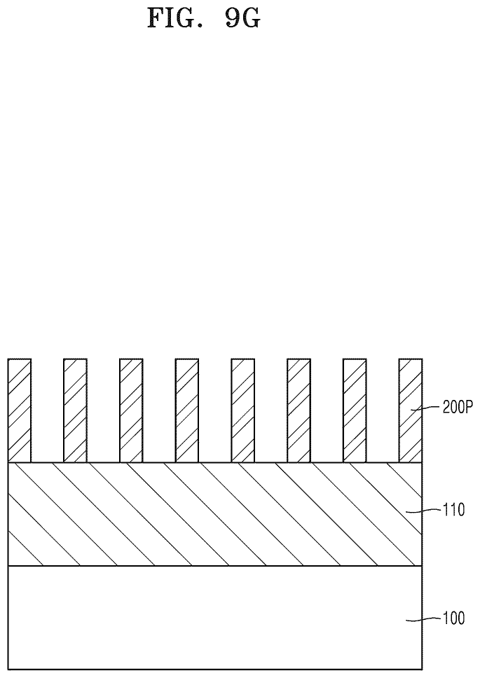

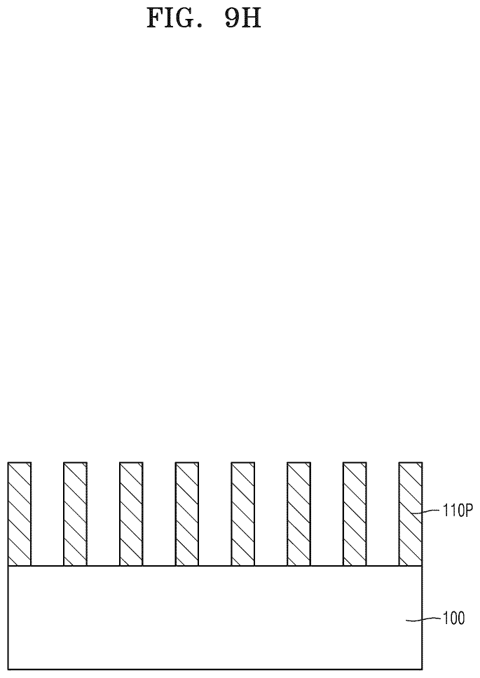

FIGS. 9A to 9H are cross-sectional views illustrating a method of manufacturing an integrated circuit device, according to an example embodiment.

Referring to FIG. 9A, a target layer 110, a lower base layer 200, an upper base layer 300, and a plurality of upper mandrel patterns 400P are sequentially formed on a substrate 100. The lower base layer 200 may be the same as or substantially similar to the base layer 200 shown in FIG. 3A, and the upper base layer 300 may be the same as substantially similar to the preliminary mandrel layer 300 shown in FIG. 3A. The lower base layer 200 may be referred to as a base layer, and the upper base layer 300 may be referred to as a preliminary mandrel layer.

The upper base layer 300 may have a stack structure including a first upper base layer 310 and a second upper base layer 320. The second upper base layer 320 may have a thickness less than that of the first upper base layer 310. The first upper base layer 310 may include a material having etch selectivity relative to the lower base layer 200. For example, the first upper base layer 310 may include a material containing C. The first upper base layer 310 and the second upper base layer 320 may include different materials. For example, the first upper base layer 310 may include C, and the second upper base layer 320 may not include C. In some example embodiments, the first upper base layer 310 may include an ACL or a C-SOH. In some example embodiments, the second upper base layer 320 may include the same material as the lower base layer 200. For example, the second upper base layer 320 may include an insulating material such as SiON or SiO₂.

Each of the upper mandrel patterns 400P may be formed to have a stack structure including an upper mandrel base pattern 410P and an upper mandrel hard mask pattern 420P. The upper mandrel hard mask pattern 420P may have a thickness less than that of the upper mandrel base pattern 410P. The upper mandrel base pattern 410P may include a material having etch selectivity relative to the second upper base layer 320. The upper mandrel base pattern 410P and the upper mandrel hard mask pattern 420p may include different materials. For example, the upper mandrel base pattern 410P may include C, and the upper mandrel hard mask pattern 420P may not include C. In some example embodiments, the upper mandrel base pattern 410P may include an ACL or a C-SOH. In some example embodiments, the upper mandrel hard mask pattern 420P may include the same material as the second upper base layer 320. For example, the upper mandrel hard mask pattern 420 may include an insulating material such as SiON or SiO₂, and in some example embodiments, the upper mandrel pattern 400P may be formed through EUV lithography.

Referring to FIG. 9B, a plurality of upper spacer patterns 460A are formed on both side surfaces of the upper mandrel patterns 400P. For example, the upper spacer patterns 460A may cover portions of the upper surface of the upper base layer 300, which are adjacent to the upper mandrel patterns 400P, and side surfaces of the upper mandrel base pattern 410P of each upper mandrel pattern 400P. The upper spacer pattern 460A may include TiO₂, HfO₂, ZrO₂, SiO₂, or SiN.

Referring to FIGS. 9B and 9C, the upper mandrel patterns 400P are removed, leaving the upper spacer patterns 460A on the upper base layer 300. The upper mandrel patterns 400P may be removed according to the same method as that used to remove the mandrel patterns 300P of FIG. 3G to 3I or the mandrel patterns 300P of FIGS. 3F, 4A, and 4B. The upper spacer patterns 460A may be formed according to the same method as that used to form the spacer patterns 360A of FIGS. 3C to 3I, the spacer patterns 360A of FIGS. 4A and 4B, or the spacer patterns 360B of FIGS. 6A and 6B.

Referring to FIGS. 9C and 9D, a plurality of lower mandrel patterns 300P are formed by patterning the upper base layer 300 by using the upper spacer patterns 460A as etch masks. The lower mandrel patterns 300P may each be formed to have a stack structure that includes the mandrel base pattern 310P, which is a portion of the first upper base layer 310, and the mandrel hard mask pattern 320P, which is a portion of the second upper base layer 320.

Referring to FIG. 9E, the lower spacer patterns 360A are formed on both side surfaces of the lower mandrel patterns 300P. For example, the lower spacer patterns 360A may cover portions of the upper surface of the lower base layer 200, which are adjacent to the lower mandrel patterns 300P, and the side surfaces of the mandrel base pattern 310P of each lower mandrel pattern 300P. The lower spacer pattern 360A may include TiO₂, HfO₂, ZrO₂, SiO₂, or SiN.

Referring to FIGS. 9E and 9F together, the lower mandrel patterns 300P are removed, leaving the lower spacer patterns 360A on the lower base layer 200. The lower mandrel patterns 300P may be removed according to the same method as that used to remove the mandrel patterns 300P of FIG. 3G to 3I or the mandrel patterns 300P of FIGS. 3F, 4A, and 4B. The lower spacer patterns 360A may be formed according to the same method as that used to form the spacer patterns 360A of FIGS. 3C to 3I, the spacer patterns 360A of FIGS. 4A and 4B, or the spacer patterns 360B of FIGS. 6A and 6B.

Referring to FIGS. 9F and 9G together, the lower base layer 200 is patterned using the lower spacer patterns 360A as etch masks, and thus, the base patterns 200P are formed. The base patterns 200P may be referred to as a plurality of hard mask patterns.

Referring to FIGS. 9G and 9H together, the target layer 110 is patterned using the base patterns 200P as etch masks, thereby forming a plurality of target patterns 110P. For example, the target patterns 110P may be a plurality of active regions or a plurality of conductive line patterns. In some example embodiments, the target patterns 110P may define a plurality of hole patterns.

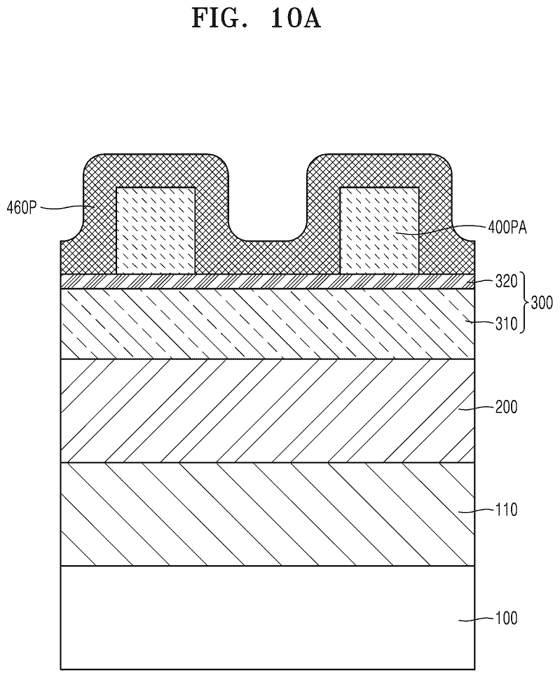

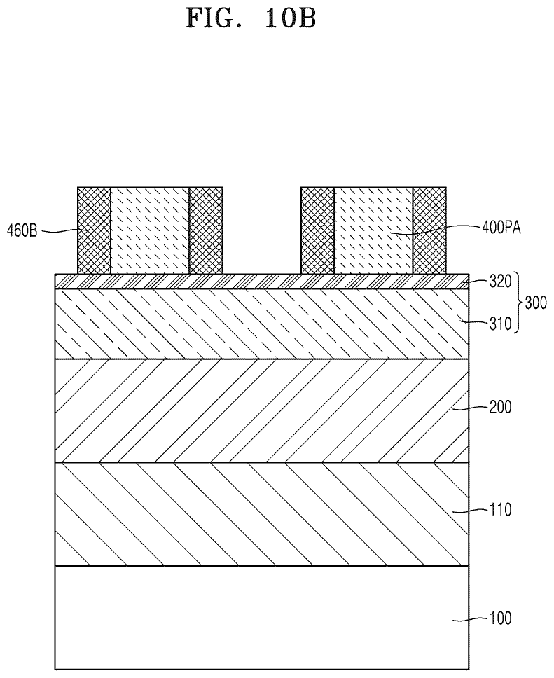

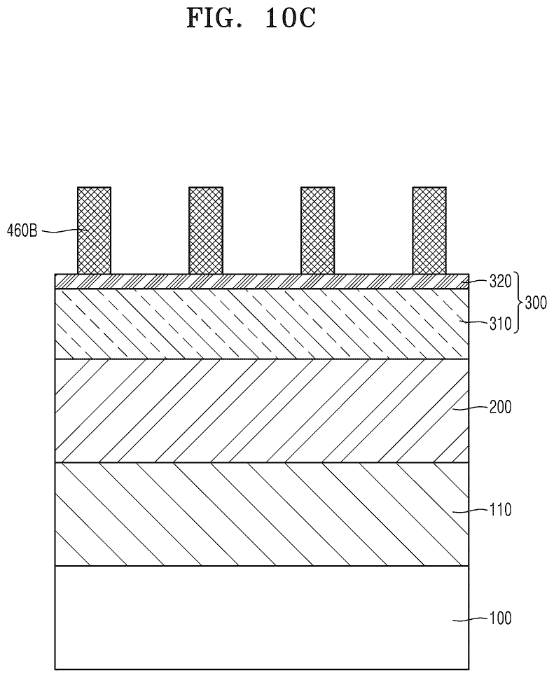

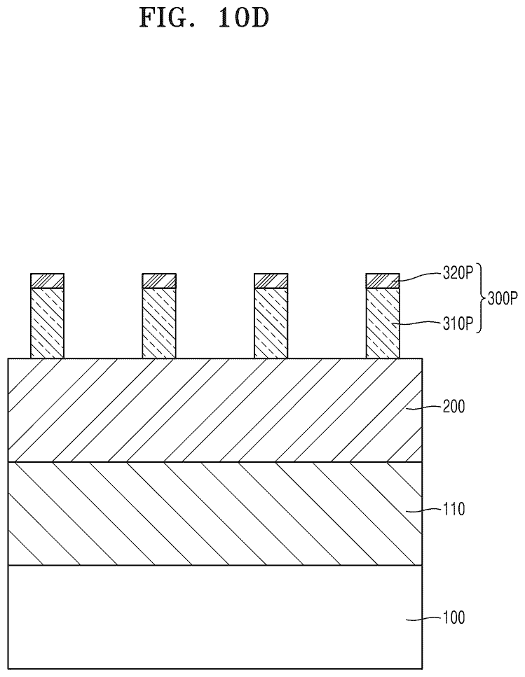

FIGS. 10A to 10D are cross-sectional views illustrating a method of manufacturing an integrated circuit device, according to an example embodiment.

Referring to FIG. 10A, a target layer 110, a lower base layer 200, an upper base layer 300, and a plurality of upper mandrel patterns 400PA are sequentially formed on a substrate 100, and then, an upper spacer layer 460P conformally covering the upper base layer 300 and the upper mandrel patterns 400PA is formed. In some example embodiments, each of the upper mandrel patterns 400PA may be a single layer. The upper mandrel pattern 400PA may include a material having etch selectivity relative to the second upper base layer 320. The upper mandrel pattern 400PA may include C. For example, the upper mandrel pattern 400PA may include an ACL or a C-SOH. In some example embodiments, the upper mandrel pattern 400PA may be formed through EUV lithography. The upper spacer layer 460P may include a material having etch selectivity relative to the upper mandrel pattern 400PA. For example, the upper spacer layer 460P may include an insulating material that does not contain C. In some example embodiments, the upper spacer layer 460P may include SiO₂, metal oxide, or SiN.

Referring to FIGS. 10A and 10B together, a plurality of upper spacer patterns 460B are formed by anisotropically etching the upper spacer layer 460P. The upper spacer patterns 460B may be formed to cover the side surfaces of the upper mandrel patterns 400PA.

Referring to FIGS. 10B and 10C together, the upper mandrel patterns 400PA are removed, leaving the upper spacer patterns 460B on the upper base layer 300.

Referring to FIGS. 10C and 10D together, the lower mandrel patterns 300P are formed by patterning the upper base layer 300 by using the upper spacer patterns 460B as etch masks. The lower mandrel patterns 300P may each be formed to have a stack structure that includes the mandrel base pattern 310P, which is a portion of the first upper base layer 310, and the mandrel hard mask pattern 320P, which is a portion of the second upper base layer 320. Then, referring to FIGS. 9E and 9H together, the base patterns 200P and the target patterns 110P may be formed.

While the inventive concepts has been particularly shown and described with reference to some example embodiments thereof, it will be understood that various changes in form and details may be made therein without departing from the spirit and scope of the following claims.

What is claimed is:

1. A method of manufacturing an integrated circuit device, the method comprising:
forming a mandrel pattern on a base layer, the mandrel pattern having a stack structure that includes a mandrel base pattern and a mandrel hard mask pattern;
attaching precursor inhibitors to a surface of the base layer and a surface of the mandrel hard mask pattern;
forming a side surface spacer layer on a side surface of the mandrel base pattern;
removing a first portion of the precursor inhibitors, leaving a second portion of the precursor inhibitors between the base layer and the side surface spacer layer;
forming a spacer bonding layer by modifying the second portion of the precursor inhibitors to bond the base layer to the side surface spacer layer, and then forming a spacer pattern with a stack structure comprising the spacer bonding layer and the side surface spacer layer;
removing the mandrel pattern; and
forming a base pattern by patterning the base layer by using the spacer pattern as an etch mask.

2. The method of claim 1, wherein, in the attaching the precursor inhibitors, the precursor inhibitors are not attached to the side surface of the mandrel base pattern.

3. The method of claim 2, wherein
each of the surface of the base layer, the surface of the mandrel base pattern, and the surface of the mandrel hard mask pattern is hydrophilic, and
the method further comprises, before the attaching the precursor inhibitors, performing surface treatment in which each of the surface of the base layer and the surface of the mandrel hard mask pattern remains hydrophilic, while the surface of the mandrel base pattern is reduced to become hydrophobic.

4. The method of claim 3, wherein the performing the surface treatment comprises performing hydrogen (H) radical treatment.

5. The method of claim 1, wherein the forming the side surface spacer layer including forming the side surface spacer layer on a surface of the mandrel base pattern and not on the surface of the base layer and the surface of the mandrel hard mask pattern.

6. The method of claim 1, wherein the forming the side surface spacer layer includes forming the side surface spacer layer such that a lower surface of the side surface spacer layer and an upper surface of the base layer are spaced apart from each other with the second portion of the precursor inhibitors therebetween.

7. The method of claim 1, wherein
the mandrel base pattern comprises a first material containing carbon, and
each of the mandrel hard mask pattern and the base layer comprises a second material that does not contain carbon but contains silicon and oxygen.

8. The method of claim 1, wherein
each of the precursor inhibitors comprises a central element, a first ligand that is a bonding moiety bonded to the central element, and a second ligand that is an inhibition moiety, and
the attaching the precursor inhibitors includes exposing the surface of the base layer and the surface of the mandrel hard mask pattern to the precursor inhibitors such that the precursor inhibitors are attached to the surface of the base layer and the surface of the mandrel hard mask pattern.

9. The method of claim 1, further comprising:
before the forming of the side surface spacer layer, performing a preprocessing process of flowing H₂O onto the base layer and the mandrel pattern.

10. The method of claim 1, wherein, the forming the spacer pattern includes converting the second portion of the precursor inhibitors into the spacer bonding layer by supplying ozone (O₃) or plasma comprising oxygen radicals (O₂, H₂O, N₂O, CO₂, or NO).

11. A method of manufacturing an integrated circuit device, the method comprising:
forming a mandrel pattern on a base layer, the mandrel pattern having a stack structure that includes a mandrel base pattern and a mandrel hard mask pattern;
exposing a surface of the base layer and a surface of the mandrel hard mask pattern to precursor inhibitors such that the precursor inhibitors are not attached to a surface of the mandrel base pattern but a first ligand of each of the precursor inhibitors is attached to the surface of the base layer and the surface of the mandrel hard mask pattern, the precursor inhibitors each including a central element, the first ligand that is a bonding moiety bonded to the central element, and a second ligand that is an inhibition moiety;
forming a side surface spacer layer on a side surface of the mandrel base pattern;
among the precursor inhibitors, leaving a first portion of the precursor inhibitors attached to a portion of the surface of the base layer between the base layer and the side surface spacer layer, and removing a second portion of the precursor inhibitors attached to another portion of the surface of the base layer and the surface of the mandrel hard mask pattern;
forming a spacer bonding layer by modifying the first portion of the precursor inhibitors to bond the base layer to the side surface spacer layer, and then forming a spacer pattern with a stack structure comprising the spacer bonding layer and the side surface spacer layer;
removing the mandrel pattern; and
forming a base pattern by patterning the base layer by using the spacer pattern as an etch mask.

12. The method of claim 11, further comprising:
before the exposing, performing surface treatment using hydrogen (H) radicals to make the surface of the mandrel base pattern hydrophobic.

13. The method of claim 11, further comprising:
before the forming the side surface spacer layer, performing a preprocessing process of flowing H₂O onto the base layer and the mandrel pattern such that the precursor inhibitors are chemically bonded to the base layer.

14. The method of claim 11, wherein
the forming the spacer bonding layer includes changing the first portion of the precursor inhibitors through treatment using ozone (O₃) or plasma comprising oxygen radicals (O₂, H₂O, N₂O, CO₂, or NO), and
the removing the mandrel pattern comprise removing the mandrel hard mask pattern.

15. The method of claim 11, wherein the forming the mandrel pattern comprises:
forming an upper base layer on the base layer, the upper base layer having a stack structure that includes a first upper base layer and a second upper base layer;
forming an upper mandrel pattern on the upper base layer;
forming an upper spacer pattern on a side surface of the upper mandrel pattern;
removing the upper mandrel pattern; and
forming the mandrel base pattern and the mandrel hard mask pattern by patterning the upper base layer by using the upper spacer pattern as an etch mask, the mandrel base pattern being a portion of the first upper base layer, the mandrel hard mask pattern being a portion of the second base layer.

16. The method of claim 15, wherein
the forming the upper mandrel pattern includes forming the upper mandrel pattern to have a stack structure comprising an upper mandrel base pattern and an upper mandrel hard mask pattern, and
the forming the upper spacer pattern includes forming the upper spacer pattern on a side surface of the upper mandrel base pattern.

17. The method of claim 15, wherein the forming the upper spacer pattern comprises:
forming an upper spacer layer by conformally covering the upper base layer and the upper mandrel pattern; and
forming the upper spacer pattern by anisotropically etching the upper spacer layer.

18. A method of manufacturing an integrated circuit device, the method comprising:
forming a mandrel pattern on a base layer, the mandrel pattern having a stack structure that includes a mandrel base pattern and a mandrel hard mask pattern;
performing surface treatment with hydrogen radicals to make each of a surface of the base layer and a surface of the mandrel hard mask pattern hydrophilic and a surface of the mandrel base pattern hydrophobic;
exposing the surface of the base layer and the surface of the mandrel hard mask pattern to precursor inhibitors such that the precursor inhibitors are attached to the surface of the base layer and the surface of the mandrel hard mask pattern through a first ligand of each of the precursor inhibitors, the precursor inhibitors each including a central element, the first ligand functioning as a bonding moiety bonded to the central element, and a second ligand functioning as an inhibition moiety;
performing a preprocessing process of flowing H₂O onto the base layer and the mandrel pattern;
forming a side surface spacer layer on a side surface of the mandrel base pattern of the mandrel pattern by using a reactant that does not react with the precursor inhibitors and a spacer deposition precursor that reacts with the reactant such that the side surface spacer layer and the base layer are spaced apart from each other with the precursor inhibitors therebetween;
among the precursor inhibitors, leaving a first portion of the precursor inhibitors attached to portions of the surface of the base layer between the base layer and the side surface spacer layer, and removing a second portion of the precursor inhibitors attached to other portions of the surface of the base layer and the surface of the mandrel hard mask pattern;
forming a spacer bonding layer, which bonds the base layer to the side surface spacer layer, by changing the first portion of the precursor inhibitors due to ozone (O₃) or plasma containing oxygen radicals (O₂, H₂O, N₂O, CO₂, or NO) and forming a spacer pattern with a stack structure comprising the spacer bonding layer and the side surface spacer layer;
removing the mandrel pattern; and
forming a base pattern by patterning the base layer by using the spacer pattern as an etch mask.

19. The method of claim 18, wherein
the mandrel base pattern comprises a first material containing carbon, and
each of the mandrel hard mask pattern and the base layer comprises a second material that does not contain carbon but contains silicon and oxygen.

20. The method of claim 18, wherein
in the exposing, the precursor inhibitors are not attached to the surface of the mandrel base pattern, and
the forming the side surface spacer layer includes forming the side surface spacer layer on the surface of the mandrel base pattern and not on the surface of the base pattern and the surface of the mandrel hard mask pattern.
